(19) United States
(12) Patent Application Publication
(10) Pub. No.: US 2023/0395750 A1
(43) Pub. Date: Dec. 7, 2023

(54) LIGHT EMITTING ELEMENT

(71) Applicant: TOYODA GOSEI CO., LTD., Kiyosu-shi (JP)

(72) Inventors: Koji OKUNO, Kiyosu-shi (JP); Koichi GOSHONOO, Kiyosu-shi (JP); Masaki OYA, Kiyosu-shi (JP)

(21) Appl. No.: 18/201,986

(22) Filed: May 25, 2023

(30) Foreign Application Priority Data
Jun. 2, 2022 (JP) 2022-090539
Jun. 2, 2022 (JP) 2022-090540
Jun. 2, 2022 (JP) 2022-090541
Nov. 9, 2022 (JP) 2022-179894
Nov. 9, 2022 (JP) 2022-179895

(51) Int. Cl. H01L 33/32; H01L 33/06; H01L 33/12

(52) U.S. Cl. CPC H01L 33/32; H01L 33/06; H01L 33/12

(57) ABSTRACT

A first intermediate layer is a semiconductor layer provided on a first active layer, and is positioned between the first active layer and a second active layer. The first intermediate layer is structured so that a non-doped layer and an n-type layer are laminated in the order from the first active layer side. A second intermediate layer is a semiconductor layer provided on the second active layer, and is positioned between the second active layer and the third active layer. The second intermediate layer is structured so that a non-doped layer and an n-type layer are laminated in the order from the second active layer side.

### CROSS-REFERENCE

This application claims priorities to Japanese patent application nos. 2022-090539 filed on Jun. 2, 2022, 2022-090540 filed on Jun. 2, 2022, 2022-090541 filed on Jun. 2, 2022, 2022-179894 filed on Nov. 9, 2022, and 2022-179895 filed on Nov. 9, 2022, the contents of which are fully incorporated herein by reference.

### TECHNICAL FIELD

The present disclosure relates to a light emitting element.

### BACKGROUND ART

In recent years, high definition has been demanded for a display, and a micro LED display with a fine LED in which one pixel is on the order of 1 μm to 100 μm has attracted attention. Various methods for producing a full-color display are known, and for example, a method in which three active layers that respectively emit light of colors of blue, green, and red are sequentially laminated on the same substrate is known. In this case, it is necessary to form an intermediate layer between the active layers in order to individually drive each active layer.

### SUMMARY

However, when the active layers are individually driven, a difference occurs in drive voltage, current injection efficiency, and reverse current due to a difference in the distance of a pn junction, and thus it has been difficult to uniformly control the active layers. Furthermore, it has been difficult to independently control two types of active layers laminated with the intermediate layer interposed therebetween.

Therefore, one object of the present disclosure is to reduce a difference in diode characteristics when each active layer is individually driven, and to independently control light emission characteristics of each active layer.

The intermediate layer has to be formed after lamination of the active layer. Therefore, it has been necessary to form the intermediate layer at a low temperature to avoid thermal damage to the active layer. However, when the intermediate layer is formed at a low temperature, there is a problem that the quality and surface flatness of the intermediate layer are deteriorated, and the quality of the active layer formed thereon is also deteriorated.

Therefore, another object of the present disclosure is to improve the surface flatness of the intermediate layer.

In the case of emitting green or red light, InGaN having a high In composition ratio is required. However, strain occurs due to lattice mismatch, and it has not been able to form high-quality InGaN.

Therefore, another object of the present disclosure is to improve the quality of the active layer.

In order to achieve red light emission by InGaN, the In composition needs to be about 40%. However, in the method disclosed in Japanese Patent No. 5854419, it has been difficult to obtain high-quality InGaN when the In composition is high.

Therefore, the other object of the present disclosure is to improve the quality of the group-III nitride semiconductor having an In composition of 35% or more.

A first aspect of the present disclosure is
a light emitting element including a group-III nitride semiconductor, comprising:
an n-layer including an type group-III nitride semiconductor;
a first active layer provided on the n-layer and having a predetermined emission wavelength;
an intermediate layer provided on the first active layer and having a non-doped layer including a non-doped group-III nitride semiconductor and an n-type layer including an n-type group-III nitride semiconductor which are laminated in the order from the first active layer side;
a second active layer provided on the intermediate layer and having an emission wavelength different from that of the first active layer;
a groove reaching the non-doped layer from the second active layer side;
a first p-layer provided on the second active layer and including a p-type group-III nitride semiconductor;
a second p-layer provided on the non-doped layer exposed to a bottom surface of the groove and including a p-type group-III nitride semiconductor;
a first p-electrode provided on the first p-layer; and
a second p-electrode provided on the second p-layer.

A second aspect of the present disclosure is a light emitting element including a group-III nitride semiconductor, comprising:
an n-layer including an n-type group-III nitride semiconductor;
a first active layer provided on the n-layer and having a predetermined emission wavelength;
an intermediate layer provided on the first active layer and including a group-III nitride semiconductor containing In; and
a second active layer provided on the intermediate layer and having an emission wavelength different from that of the first active layer, wherein
the intermediate layer has an In composition set so as to have a band gap that does not absorb light emitted from the first active layer and the second active layer.

A third aspect of the present disclosure is a light emitting element including a group-III nitride semiconductor, comprising:
an n-layer including an n-type group-III nitride semiconductor;
a first active layer provided on the n-layer and having a predetermined emission wavelength;
an intermediate layer provided on the first active layer;
a second active layer provided on the intermediate layer and having an emission wavelength longer than the first active layer;
a groove reaching the intermediate layer from the second active layer side;
a first p-layer provided on the second active layer and including a p-type group-III nitride semiconductor;
a second p-layer provided on the intermediate layer exposed to a bottom surface of the groove and including a p-type group-III nitride semiconductor;
a first p-electrode provided on the first p-layer; and
a second p-electrode provided on the second p-layer, wherein
the second active layer is structured so that a strain relaxation layer having a quantum well structure in which a thickness of a well layer is adjusted not to emit light and a light emitting layer having a quantum well structure and emitting light are laminated in the order from the intermediate layer side, and
a wavelength corresponding to band edge energy of the well layer of the strain relaxation layer is set to be shorter than an emission wavelength of the light emitting layer.

According to the first aspect of the present disclosure, it is possible to reduce a difference in light emission characteristics when each active layer is individually driven.

According to the second aspect of the present disclosure, it is possible to improve the surface flatness of the intermediate layer.

According to the third aspect of the present disclosure, it is possible to improve the quality of the active layer.

### BRIEF DESCRIPTION OF THE DRAWINGS

FIG. 1 is a view showing a configuration of a light emitting element of a first embodiment;

FIG. 2 is a view showing a configuration of a light emitting element of a modification;

FIG. 3 is a view showing a configuration of a light emitting element of the modification;

FIG. 4 is a view showing an equivalent circuit of the light emitting element of the first embodiment;

FIG. 5 is a view showing a manufacturing process of the light emitting element of the first embodiment;

FIG. 6 is a view showing the manufacturing process of the light emitting element of the first embodiment;

FIG. 7 is a view showing the manufacturing process of the light emitting element of the first embodiment;

FIG. 8 is a view showing the manufacturing process of the light emitting element of the first embodiment;

FIG. 9 is a view showing a configuration of a light emitting element of a second embodiment;

FIG. 10 is a view showing a configuration of a light emitting element of a third embodiment;

FIG. 11 is a view showing a configuration of a light emitting element of Experimental Example 1;

FIG. 12 is an AFM image obtained by photographing a surface of a third active layer 18;

FIG. 13 is a graph showing a relationship between a drive current and external quantum efficiency;

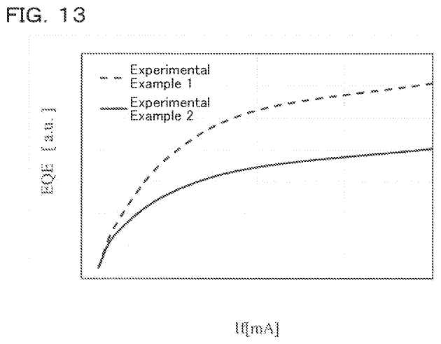

FIG. 14 is a graph showing emission spectra;

FIG. 15 is a graph showing emission spectra;

FIG. 16 is a graph showing emission spectra;

FIG. 17 is a graph showing emission spectra;

FIG. 18 is an AFM image obtained by photographing the surface of the third active layer 18;

FIG. 19 is a graph showing a relationship between a drive current and external quantum efficiency;

FIG. 20 is a view showing a configuration of a light emitting element in a fourth embodiment;

FIG. 21 is a view showing an equivalent circuit of the light emitting element in a fourth embodiment;

FIG. 22 is a view showing a configuration of a light emitting element in a fifth embodiment;

FIGS. 23A to 23C are AFM images of a well layer surface of a quantum well structure layer 518C when a growth rate is varied;

FIGS. 24A to 24D are AFM images of the well layer surface of the quantum well structure layer 518C when an In solid phase ratio/In gas phase ratio is varied; and

FIGS. 25A to 25C are AFM images of the well layer surface of the quantum well structure layer 518C when a partial pressure of ammonia is varied.

### DETAILED DESCRIPTION OF PREFERRED EMBODIMENTS

### 1. First Aspect

A light emitting element including a group-III nitride semiconductor comprises: an n-layer including an n-type group-III nitride semiconductor;
a first active layer provided on the n-layer and having a predetermined emission wavelength; an intermediate layer provided on the first active layer and having a non-doped layer including a non-doped group-III nitride semiconductor and an n-type layer including an n-type group-III nitride semiconductor which are laminated in the order from the first active layer side; a second active layer provided on the intermediate layer and having an emission wavelength different from that of the first active layer; a groove reaching the non-doped layer from the second active layer side; a first p-layer provided on the second active layer and including a p-type group-III nitride semiconductor; a second p-layer provided on the non-doped layer exposed to a bottom surface of the groove and including a p-type group-III nitride semiconductor; a first p-electrode provided on the first p-layer; and a second p-electrode provided on the second p-layer.

The intermediate layer may have a thickness of 150 nm or less, and the non-doped layer and the n-type layer may have a thickness of 10 nm or more.

The intermediate layer may include a group-III nitride semiconductor containing In, and may have an In composition set so as to have a band gap that does not absorb light emitted from the first active layer and the second active layer.

The second active layer may be structured so that a strain relaxation layer having a quantum well structure in which a thickness of a well layer is adjusted not to emit light and a light emitting layer having a quantum well structure and emitting light are laminated in the order from the intermediate layer side, and
a wavelength corresponding to band edge energy of the well layer of the strain relaxation layer may be set to be shorter than an emission wavelength of the light emitting layer.

A manufacturing method of a light emitting element including a group-III nitride semiconductor includes: a process of forming an n-layer including an n-type group-III nitride semiconductor; a process of forming a first active layer having a predetermined emission wavelength on the n-layer; a process of forming an intermediate layer having a growth temperature of 700° C. to 1000° C. on the first active layer by laminating a non-doped layer including a non-doped group-III nitride semiconductor and an n-type layer including an n-type group-III nitride semiconductor in the order from the first active layer side; a process of forming a second active layer having an emission wavelength different from that of the first active layer on the intermediate layer; a process of forming a groove reaching the non-doped layer from the second active layer side; a process of forming a first p-layer and a second p-layer both including a p-type group-III nitride semiconductor on the second active layer and the non-doped layer exposed to a bottom surface of the groove, respectively; and forming a first p-electrode and a second p-electrode on the first p-layer and the second p-layer, respectively.

The intermediate layer may have a thickness of 150 nm or less, and the non-doped layer and the n-type layer may have a thickness of 10 nm or more.

### 2. Second Aspect

A light emitting element including a group-III nitride semiconductor includes: an n-layer including an n-type group-III nitride semiconductor; a first active layer provided on the n-layer and having a predetermined emission wavelength; an intermediate layer provided on the first active layer and including a group-III nitride semiconductor containing In; and a second active layer provided on the intermediate layer and different in emission wavelength from the first active layer. The intermediate layer has an In composition set so as to have a band gap that does not absorb light emitted from the first active layer and the second active layer.

The light emitting element may include: a groove reaching the intermediate layer from the second active layer side; a first p-layer provided on the second active layer and including a p-type group-III nitride semiconductor; a second p-layer provided on the intermediate layer exposed to a bottom surface of the groove and including a p-type group-III nitride semiconductor; a first p-electrode provided on the first p-layer, and a second p-electrode provided on the second p-layer.

The intermediate layer may have a structure in which a p-type first layer, a p-type second layer, an n-type third layer, and an n-type fourth layer are laminated in the order from the first active layer side, a p-type impurity concentration of the second layer may be higher than a p-type impurity concentration of the first layer, an n-type impurity concentration of the third layer is higher than an n-type impurity concentration of the fourth layer, and the second layer and the third layer form a tunnel junction structure, and the light emitting element may include a p-layer provided on the second active layer, a groove reaching the fourth layer from the p-layer side, a p-electrode provided on the p-layer, and an electrode provided on the fourth layer exposed to a bottom surface of the groove. This configuration can prevent existence of a regrown interface and curtail deterioration of device characteristics.

In compositions of the second layer and the third layer may be higher than In compositions of the first layer and the fourth layer. The tunnel probability by the tunnel junction structure can be further increased. The In composition of the second layer may be higher than the In composition of the third layer. The thickness of the second layer may be thinner than the thickness of the first layer, and the thickness of the third layer may be thinner than the thickness of the fourth layer.

The intermediate layer may be made of InGaN. The In composition of the intermediate layer may be 10% or less. The intermediate layer may be made of GaN doped with In.

A manufacturing method of a light emitting element including a group-III nitride semiconductor includes: a process of forming an n-layer including an n-type group-III nitride semiconductor; a process of forming a first active layer having a predetermined emission wavelength on the n-layer; a process of forming, at a growth temperature of 700° C. to 1000° C., an intermediate layer including a group-III nitride semiconductor containing In on the first active layer; and a process of forming a second active layer having an emission wavelength different from that of the first active layer on the intermediate layer. The intermediate layer has the In composition set so as to have a band gap that does not absorb light emitted from the first active layer and the second active layer.

The manufacturing method may include: a process of forming a groove reaching the intermediate layer from the second active layer side; a process of forming a first p-layer and a second p-layer including a p-type group-III nitride semiconductor on the second active layer and the intermediate layer exposed to a bottom surface of the groove, respectively; and forming a first p-electrode and a second p-electrode on the first p-layer and the second p-layer, respectively.

The intermediate layer may be formed by laminating a p-type first layer, a p-type second layer, an n-type third layer, and an n-type fourth layer in order from the first active layer side, a p-type impurity concentration of the second layer may be made higher than a p-type impurity concentration of the first layer, an n-type impurity concentration of the third layer may be made higher than an n-type impurity concentration of the fourth layer, the second layer and the third layer may form a tunnel junction structure, and the manufacturing method may include a process of forming a p-layer on the second active layer, a process of forming a groove reaching the fourth layer from the p-layer side; a process of forming a p-electrode on the p-layer, and a process of forming an electrode on the fourth layer exposed to a bottom surface of the groove.

In the manufacturing method of a light emitting element including the group-III nitride semiconductor, the In compositions of the second layer and the third layer may be made higher than the In compositions of the first layer and the fourth layer. The In composition of the second layer may be made higher than the In composition of the third layer. The thickness of the second layer may be made thinner than the thickness of the first layer, and the thickness of the third layer may be made thinner than the thickness of the fourth layer. The growth temperatures of the second layer and the third layer may be made lower than the growth temperatures of the first layer and the fourth layer.

In the manufacturing method of a light emitting element including the group-III nitride semiconductor, the In composition of the intermediate layer may be made 10% or less. The intermediate layer may be InGaN. The intermediate layer may be GaN doped with In.

### 3. Third Aspect

A light emitting element including a group-III nitride semiconductor includes: an n-layer including an n-type group-III nitride semiconductor; a first active layer provided on the n-layer and having a predetermined emission wavelength; an intermediate layer provided on the first active layer; a second active layer provided on the intermediate layer and longer in emission wavelength than the first active layer; a groove reaching the intermediate layer from the second active layer side; a first p-layer provided on the second active layer and including a p-type group-III nitride semiconductor; a second p-layer provided on the intermediate layer exposed to a bottom surface of the groove and including a p-type group-III nitride semiconductor; a first p-electrode provided on the first p-layer; and a second p-electrode provided on the second p-layer.

The second active layer is structured so that a strain relaxation layer having a quantum well structure in which a thickness of a well layer is adjusted not to emit light and a light emitting layer having a quantum well structure and emitting light are laminated in the order from the intermediate layer side. The wavelength corresponding to band edge energy of the well layer of the strain relaxation layer is set to be shorter than the emission wavelength of the light emitting layer.

The wavelength corresponding to band edge energy of the well layer of the strain relaxation layer may be set to be equal to the emission wavelength of the first active layer.

The wavelength corresponding to band edge energy of the well layer of the strain relaxation layer may be set to be shorter by 40 nm to 100 nm than the emission wavelength of the light emitting layer.

The strain relaxation layer may have a single quantum well (SQW) structure.

The ratio of the thickness of the first active layer to the thickness of the second active layer may be 30% or less.

A manufacturing method of a light emitting element including a group-III nitride semiconductor includes: a process of forming an n-layer including an n-type group-III nitride semiconductor; a process of forming a first active layer having a predetermined emission wavelength on the n-layer; a process of forming, at a growth temperature of 700° C. to 1000° C., an intermediate layer including a group-III nitride semiconductor on the first active layer; a process of forming a second active layer having an emission wavelength longer than that of the first active layer on the intermediate layer; a process of forming a groove reaching the intermediate layer from the second active layer side; a process of forming a first p-layer and a second p-layer including a p-type group-III nitride semiconductor on the second active layer and the intermediate layer exposed to a bottom surface of the groove, respectively; and forming a first p-electrode and a second p-electrode on the first p-layer and the second p-layer, respectively.

The second active layer is formed by laminating a strain relaxation layer having a quantum well structure in which a thickness of a well layer is adjusted not to emit light and a light emitting layer having a quantum well structure and emitting light in the order from the intermediate layer side. The wavelength corresponding to band edge energy of the well layer of the strain relaxation layer is set to be shorter than the emission wavelength of the light emitting layer.

The wavelength corresponding to band edge energy of the well layer of the strain relaxation layer may be set to be equal to the emission wavelength of the first active layer.

The wavelength corresponding to band edge energy of the well layer of the strain relaxation layer may be set to be shorter by 40 nm to 100 nm than the emission wavelength of the light emitting layer.

The strain relaxation layer may have a SQW structure.

The ratio of the thickness of the first active layer to the thickness of the second active layer may be 30% or less.

### 4. Fourth Aspect

A manufacturing method of a group-III nitride semiconductor is a manufacturing method of a group-III nitride semiconductor in which a group-III nitride semiconductor having an In composition of 35% or more is formed by an MOCVD method, and the group-III nitride semiconductor is formed at a growth temperature of 550° C., to 700° C., a growth rate of 0.8 nm/min or less, and an In solid phase ratio/In gas phase ratio of 0.75 to 1.

The partial pressure of an N source gas may be made to 0.15 atm to 0.2 atm. The VIII ratio may be made to 30000 to 80000. The In gas phase ratio may be made to 40% or more. The partial pressure of a Ga source gas may be made to 1×10⁻⁶ atm to 3×10⁻⁶ atm, and the partial pressure of an In source gas may be made to 1×10⁻⁶ atm to 3×10⁻⁶ atm.

A manufacturing method of a light emitting element is a manufacturing method of a light emitting element including a group-III nitride semiconductor having a quantum well structure layer of emission colors of yellow to red, in which a well layer of the quantum well structure layer is formed by the manufacturing method of the group-III nitride semiconductor described above.

The manufacturing method may include: a first strain relaxation layer formation process of adjusting a thickness of a well layer so as not to emit light and forming a first strain relaxation layer in which a wavelength corresponding to band edge energy of the well layer is blue, the first strain relaxation layer having a quantum well structure; a second strain relaxation layer formation process of adjusting a thickness of a well layer so as not to emit light and forming a second strain relaxation layer in which a wavelength corresponding to band edge energy of the well layer is green, the second strain relaxation layer having a quantum well structure; and a quantum well structure layer formation process of forming the quantum well structure layer on the second strain relaxation layer.

The growth temperature of a well layer of the quantum well structure layer may be made lower than the growth temperatures of the first strain relaxation layer and the second strain relaxation layer. The growth temperature of the second strain relaxation layer may be made lower than the growth temperature of the first strain relaxation layer.

The growth rate of a well layer of the quantum well structure layer may be made slower than the growth rates of the first strain relaxation layer and the second strain relaxation layer. The growth rate of the second strain relaxation layer may be made slower than the growth rate of the first strain relaxation layer.

The In gas phase ratio at the time of forming the well layer of the quantum well structure layer may be made smaller than the In gas phase ratio at the time of forming the first strain relaxation layer and the second strain relaxation layer.

The growth rate of a barrier layer of the quantum well structure layer laminated after formation of the well layer of the quantum well structure layer may be made equal to or greater than the growth temperature of the well layer. The growth temperature of a barrier layer of the quantum well structure layer laminated after formation of the well layer of the quantum well structure layer may be made at the same temperature as the growth temperature of the well layer.

### 5. First Embodiment

5-1. Configuration of Light Emitting Element

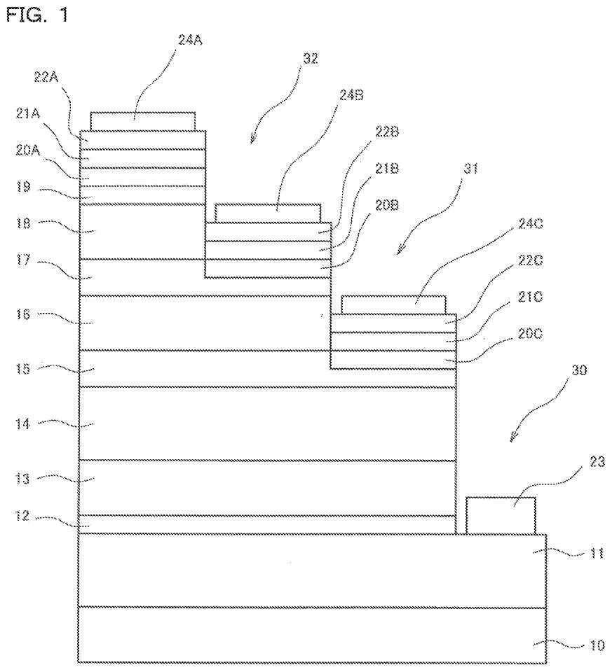

FIG. 1 is a view showing the configuration of the light emitting element of the first embodiment. The light emitting element of the first embodiment can emit each of blue, green, and red light. The light emitting element of the first embodiment is a flip-chip type that extracts light from the back surface side of a substrate, and is mounted face down on a mounting substrate not shown. Note that the first embodiment assumes a structure in which one pixel is one chip, but may be a monolithic structure. That is, a micro LED display element in which the element structure of the first embodiment is arrayed in a matrix on the same substrate may be used.

As shown in FIG. 1, the light emitting element of the first embodiment includes a substrate 10, an n-layer 11, an ESD layer 12, an underlayer 13, a first active layer 14, a first intermediate layer 15, a second active layer 16, a second intermediate layer 17, a third active layer 18, a protective layer 19, regrowth layers 20A to 20C, electron block layers 21A to 21C, the p-layers 22A to 22C, an n-electrode 23, and p-electrodes 24A to 24C.

The substrate 10 is a growth substrate for growing a group-III nitride semiconductor. Examples thereof include sapphire, Si, and GaN.

The n-layer 11 is an n-type semiconductor provided on the substrate 10 with a low-temperature buffer layer or a high-temperature buffer layer (not shown) interposed therebetween. However, the buffer layer is only required to be provided as necessary, and the buffer layer needs not be provided in a case where the substrate is GaN. The p-layer 11 is, for example, n-GaN, n-AlGaN, or the like. The Si concentration is, for example, 1×10¹⁸ cm⁻³ to 100×10¹⁸ cm⁻³.

The ESD layer 12 is a semiconductor layer provided on the n-layer 11, and is a layer provided for improving electrostatic withstand voltage. The ESD layer 12 is only required to be provided as necessary, and may be omitted. The ESD layer 12 is, for example, GaN, InGaN, or AlGaN that is non-doped or doped with Si at a low concentration.

The underlayer 13 is a semiconductor layer having a superlattice structure provided on the ESD layer 12, and is a layer for relaxing lattice strain of the semiconductor layer formed on the underlayer 13. The underlayer 13 is also only required to be provided as necessary, and may also be omitted. The underlayer 13 is formed by alternately laminating group-III nitride semiconductor thin films (for example, two from GaN, InGaN, and AlGaN) having different compositions, and the number of pairs is, for example, 3 to 30. Those non-doped or doped with Si about 1×10¹⁷ cm⁻³ to 100×10¹⁷ cm⁻³ may be adopted. It is not necessary to have a superlattice structure as long as strain can be relaxed. Any material may be used as long as a lattice constant difference becomes small at a hetero interface with the first active layer 14, and for example, an InGaN layer, an AlInN layer, or an AlGaIn layer may be used.

The first active layer 14 is a light emitting layer having a single quantum well (SQW) structure or a multiple quantum well (MQW) structure provided on the underlayer 13. The emission wavelength is blue and 430 nm to 480 nm. The first active layer 14 has a structure in which 1 to 7 pairs of barrier layers including AlGaN and well layers including InGaN are alternately laminated. The number of pairs is more preferably 1 to 5 and still more preferably 1 to 3.

The first intermediate layer 15 is a semiconductor layer provided on the first active layer 14, and is positioned between the first active layer 14 and the second active layer 16. The first intermediate layer 15 is a layer provided for individually enabling control light emission from the first active layer 14 and light emission from the second active layer 16. The first intermediate layer 15 also serves to protect the first active layer 14 from etching damage when a second groove 31 described later is formed.

The material of the first intermediate layer 15 is a group-III nitride semiconductor containing In, and is preferably InGaN, for example. The roughness of the surface of the first intermediate layer 15 can be reduced by the surfactant effect by In, and the surface flatness can be improved. Lattice strain can be relaxed. The In composition of the first intermediate layer 15 (molar ratio of In to the entire group-III metal of the group-III nitride semiconductor) is only required to be set so as to have a band gap that does not absorb light emitted from the first active layer 14 and the second active layer 16. The In composition is preferably 10% or less, more preferably 5% or less, and still more preferably 2% or less. The In composition that is more than 10% causes roughness of the surface of the first intermediate layer 15. In is arbitrary as long as it is larger than 0%, and may be at a doping level (level at which a mixed crystal is not formed). For example, GaN having an In concentration of 1×10¹⁴ cm⁻³ or more and 1×10²² cm⁻³ or less is used.

The first intermediate layer 15 may be doped with an impurity. The impurity is preferably an n-type impurity. For example, the Si concentration may be 1×10¹⁷ cm⁻³ to 1000×10¹⁷ cm⁻³, preferably 10×10¹⁷ cm⁻³ to 100×10¹⁷ cm⁻³, more preferably 20×10¹⁷ cm⁻³ to 80×10¹⁷ cm⁻³.

The thickness of the first intermediate layer 15 is preferably made 20 nm to 150 nm. The thickness thicker than 150 nm can cause roughness of the surface of the first intermediate layer 15. The thickness thinner than 20 nm can make it difficult to control the depth of the second groove 31 to be in the first intermediate layer 15 when the second groove 31 described later is formed. The thickness is more preferably 30 nm to 100 nm and still more preferably 50 nm to 80 nm.

The second active layer 16 is a light emitting layer having a SQW or MQW structure provided on the first intermediate layer 15. The emission wavelength is green and 510 nm to 570 nm. The second active layer 16 has a structure in which 1 to 7 pairs of barrier layers including GaN and well layers including InGaN are alternately laminated. The number of pairs is more preferably 1 to 5 and still more preferably 1 to 3. The number of pairs is preferably equal to or smaller than the number of pairs of the first active layer 14, and more preferably smaller.

The second intermediate layer 17 is a semiconductor layer provided on the second active layer 16, and is positioned between the second active layer 16 and the third active layer 18. The second intermediate layer 17 is provided for the same reason as the first intermediate layer 15, and is a layer provided for individually enabling control light emission from the second active layer 16 and light emission from the third active layer 18. The second intermediate layer 17 also has a role of protecting the second active layer 16 from etching damage when a third groove 32 described later is formed.

The material of the second intermediate layer 17 is similar to that of the first intermediate layer 15. The first intermediate layer 15 and the second intermediate layer 17 may include the same material. Similarly to the first intermediate layer 15, the second intermediate layer 17 may also be doped with an impurity. The thickness of the second intermediate layer 17 is also similar to that of the first intermediate layer 15, and the thicknesses of the first intermediate layer 15 and the second intermediate layer 17 may be the same. However, it is preferable to make it thinner than the first intermediate layer 15 and to make the In composition larger than that of the first intermediate layer 15. This is because the second active layer 16 emitting green light is more prone to thermal damage than the first active layer 14 emitting blue light is, and the influence of strain at the interface becomes large.

The third active layer 18 is a light emitting layer having a SQW or MQW structure provided on the second intermediate layer 17. The emission wavelength is red and 590 nm to 700 nm. The third active layer 18 has a structure in which 1 to 7 pairs of barrier layers including InGaN and well layers including InGaN are alternately laminated. The number of pairs is more preferably 1 to 5 and still more preferably 1 to 3. The number of pairs is preferably equal to or smaller than the number of pairs of the second active layer 16, and more preferably smaller.

The protective layer 19 is a semiconductor layer provided on the third active layer 18. The protective layer 19 is a layer that protects the active layer and also functions as an electron block layer. The protective layer 19 is only required to be a material wider in band gap than the well layer of the third active layer 18, and is AlGaN, GaN, InGaN, or the like. The thickness of the protective layer 19 is preferably 2.5 nm to 50 nm and more preferably 5 nm to 25 nm. The protective layer 19 may be doped with an impurity or may be doped with Mg. In this case, the Mg concentration is preferably 1×10¹⁸ cm⁻³ to 1000×10¹⁸ cm⁻³.

A partial region of the protective layer 19 is etched to provide a groove, and is provided with the third groove 32 reaching the second intermediate layer 17 from the protective layer 19, the second groove 31 reaching the first intermediate layer 15, and a first groove 30 reaching the n-layer 11.

The regrowth layers 20A to 20C are provided on the protective layer 19, the second intermediate layer 17 exposed to the bottom surface of the third groove 32, and the first intermediate layer 15 exposed to the bottom surface of the second groove 31, respectively. The configuration of the regrowth layers 20A to 20C are similar to that of the protective layer 19.

The electron block layers 21A to 21C are semiconductor layers provided on the regrowth layers 20A to 20C, respectively, and are layers that block electrons injected from the n-layer 11 for efficiently confining the electrons in the first active layer 14, the second active layer 16, and the third active layer 18. The electron block layer may be a single layer of GaN or AlGaN, or may have a structure in which two or more of AlGaN, GaN, and InGaN are laminated, or a structure in which they are laminated with only the composition ratio being varied. A superlattice structure may be adopted. The thickness of each of the electron block layers 21A to 21C is preferably 5 nm to 50 nm and more preferably 5 nm to 25 nm. The Mg concentration of the electron block layers 21A to 21C is preferably 1×10¹⁹ cm⁻³ to 100×10¹⁹ cm⁻³.

The p-layers 22A to 22C are semiconductor layers provided on the electron block layers 21A to 21C, respectively, and include the first layer and the second layer in order from the electron block layer 21 side. The first layer is preferably p-GaN or p-InGaN. The thickness of the first layer is preferably 10 nm to 500 nm, more preferably 10 nm to 200 nm, and still more preferably 10 nm to 100 nm. The Mg concentration of the first layer is preferably 1×10¹⁹ cm⁻³ to 100×10¹⁹ cm⁻³. The second layer is preferably p-GaN or p-InGaN. The thickness of the second layer is preferably 2 nm to 50 nm, more preferably 4 nm to 20 nm, and still more preferably 6 nm to 10 nm. The Mg concentration of the second layer is preferably 1×10²⁰ cm⁻³ to 100×10²⁰ cm⁻³.

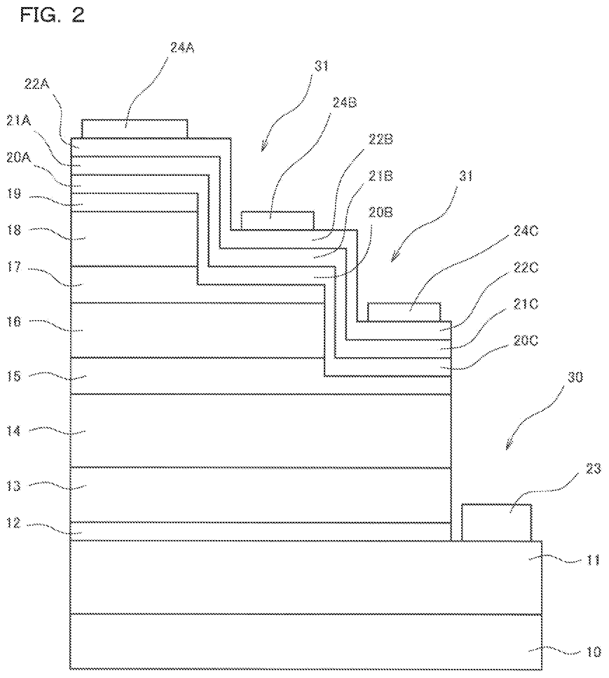

In the first embodiment, the regrowth layers 20A to 20C, the electron block layers 21A to 21C, and the p-layers 22A to 22C are separately provided, but may be continuous (see FIG. 2). In this case, the regrowth layer, the electron block layer, and the p-layer are also formed on a side surface of the third groove 32 and a side surface of the second groove 31, but they hardly affect the operation of the element. The reason is as follows. If the p-electrode 24A, the p-electrode 24B, and the p-electrode 24C are spatially sufficiently separated from one another, the resistance of the p-layer connecting among the p-electrode 24A, the p-electrode 24B, and the p-electrode 24C is very high, and thus a current hardly flows. In addition, since a hole is low in mobility, the hole does not spread in the lateral direction from a region in contact with an electrode, and flows predominantly in the longitude direction through a pn junction immediately below the electrode. Therefore, even if the regrowth layers 20A to 20C, the electron block layers 21A to 21C, and the p-layers 22A to 22C are continuous, the operation of the element is not affected. That is, when a current flows through the p-electrode 24A, the current flows immediately below the p-electrode 24A, and as a result, the active layer immediately below the p-electrode 24A emits light, and the current hardly flows through the active layers immediately below the p-electrodes 24B and 24C to emit light.

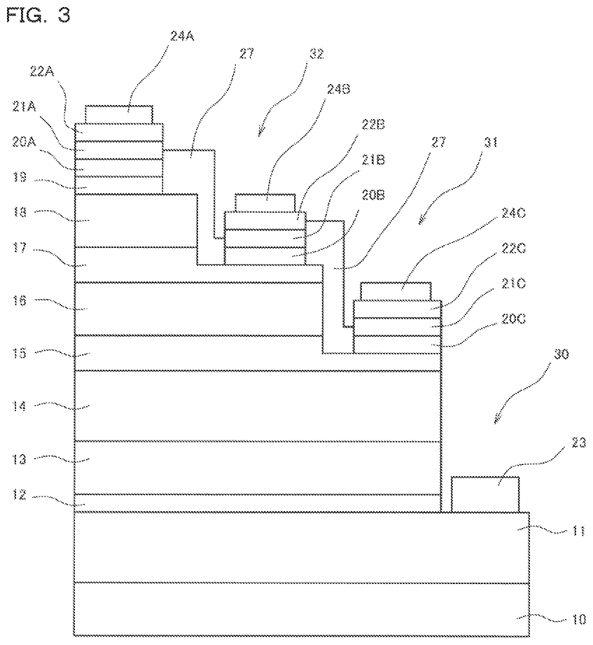

As in FIG. 3, the side surface of the third groove 32 or the side surface of the second groove 31 may be provided with an insulating film 27. This insulating film 27 leaves a mask for selectively growing the regrowth layers 20A to 20C, the electron block layers 21A to 21C, and the p-layers 22A to 22C.

The n-electrode 23 is an electrode provided on the n-layer 11 exposed to a bottom surface of the first groove 30. When the substrate 10 is including a conductive material, the n-electrode 23 may be provided on a back surface of the substrate 10 without providing the first groove 30. The material of the n-electrode 23 is, for example, Ti/Al.

The p-electrodes 24A to 24C are electrodes provided on the p-layers 22A to 22C, respectively. The material of the p-electrodes 24A to 24C is, for example, Ag, Ni/Au, Co/Au, or ITO.

5-2. Operation of Light Emitting Element

The operation of the light emitting element of the first embodiment will be described. The light emitting element of the first embodiment can emit red light from the third active layer 18 by applying a voltage between the p-electrode 24A and the n-electrode 23, can emit green light from the second active layer 16 by applying a voltage between the p-electrode 24B and the n-electrode 23, and can emit blue light from the first active layer 14 by applying a voltage between the p-electrode 24C and the n-electrode 23. Two or more of blue, green, and red can be simultaneously emitted. As described above, the light emitting element of the first embodiment can control blue, green, and red emission by selection of an electrode applied with the voltage, and the light emitting element can be used as one pixel of display.

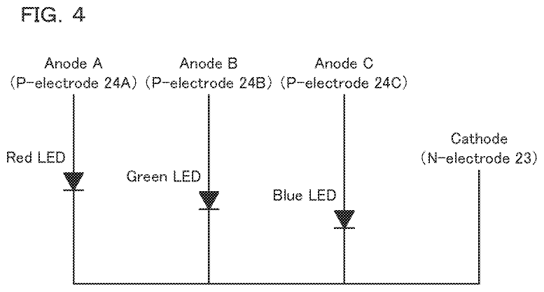

FIG. 4 shows an equivalent circuit of the light emitting element of the first embodiment. As shown in FIG. 4, the light emitting element of the first embodiment has a structure in which blue, green, and red LEDs are formed in one element, and full color light emission can be achieved by one element. Therefore, the size of one element can be made very small as compared with a case where blue, green, and red LEDs are individually prepared and arrayed on the same substrate to produce a full-color light emitting element of one pixel. Furthermore, the structure of the first embodiment can omit the process of individually preparing and arraying the blue, green, and red LEDs, can significantly reduce the manufacturing cost, and can achieve an extremely low-cost full-color light emitting element and a light emitting display applied with the same.

Here, in the first embodiment, since the first intermediate layer 15 and the second intermediate layer 17 contain In, the surface flatness of the first intermediate layer 15 and the second intermediate layer 17 can be improved by the surfactant effect of In, and the surface flatness of the second active layer 16 and the third active layer 18 can also be improved. Lattice strain caused by a lattice constant difference between the underlayer 13 and the first active layer 14 can also be relaxed. As a result, according to the light emitting element of the first embodiment, the light emission efficiency can be improved.

5-3. Manufacturing Method of Light Emitting Element

Next, a manufacturing process of the light emitting element of the first embodiment will be described with reference to the drawings.

First, the substrate 10 is prepared, and hydrogen, nitrogen, and if necessary, ammonia are added, and the substrate is subjected to heat treatment.

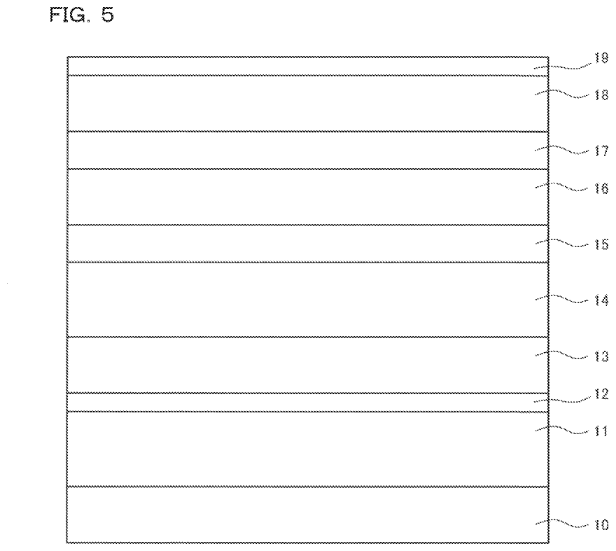

Next, a buffer layer is formed on the substrate 10, and the n-layer 11, the ESD layer 12, the underlayer 13, the first active layer 14, the first intermediate layer 15, the second active layer 16, the second intermediate layer 17, the third active layer 18, and the protective layer 19 are formed on the buffer layer in the order from the buffer layer side (see FIG. 5). A preferred growth temperature of each layer is as follows.

The growth temperature of the first active layer 14 is preferably 700° C. to 950° C. The crystal quality can be improved, and the light emission efficiency can be enhanced. The first active layer 14 includes a well layer and a barrier layer, but the well layer and the barrier layer may be formed at the same temperature, or may be formed at different temperatures within the above temperature range. In a case of setting different temperatures, the growth temperature of the well layer is preferably lower than the growth temperature of the barrier layer.

The growth temperature of the first intermediate layer 15 is preferably 700° C. to 1000° C. This is to reduce thermal damage to the first active layer 14. When the temperature is lower than 700° C., pits and point defects caused by threading dislocation become prone to occur. The temperature is more preferably 800° C. to 950° C. and still more preferably 850° C. to 950° C.

The growth temperature of the second active layer 16 is preferably 650° C. to 950° C. The crystal quality can be improved, and the light emission efficiency can be enhanced. The second active layer 16 includes a well layer and a barrier layer, but the well layer and the barrier layer may be formed at the same temperature, or may be formed at different temperatures within the above temperature range. In a case of setting different temperatures, the growth temperature of the well layer is preferably made lower than the growth temperature of the barrier layer. The growth temperature of the second active layer 16 is preferably lower than the growth temperature of the first active layer 14.

The growth temperature of the second intermediate layer 17 is preferably in the same range as the growth temperature of the first intermediate layer 15. However, the growth temperature of the second intermediate layer 17 is preferably made lower than the growth temperature of the first intermediate layer 15. This is because the second active layer 16 emitting green light is more prone to thermal damage than the first active layer 14 emitting blue light is, and the influence of strain at the interface becomes large.

The growth temperature of the third active layer 18 is preferably 500° C. to 950° C. The crystal quality can be improved, and the light emission efficiency can be enhanced. The third active layer 18 includes a well layer and a barrier layer, but the well layer and the barrier layer may be formed at the same temperature, or may be formed at different temperatures within the above temperature range. In a case of setting different temperatures, the growth temperature of the well layer is preferably made lower than the growth temperature of the barrier layer. The growth temperature of the third active layer 18 is preferably lower than the growth temperature of the second active layer 16.

The growth temperature of the protective layer 19 is preferably 500° C. to 950° C. This is to reduce thermal damage to the first active layer 14, the second active layer 16, and the third active layer 18. For improving the crystallinity of the protective layer 19, the growth temperature is preferably higher, more preferably 600° C. to 900° C., and still more preferably 700° C. to 900° C.

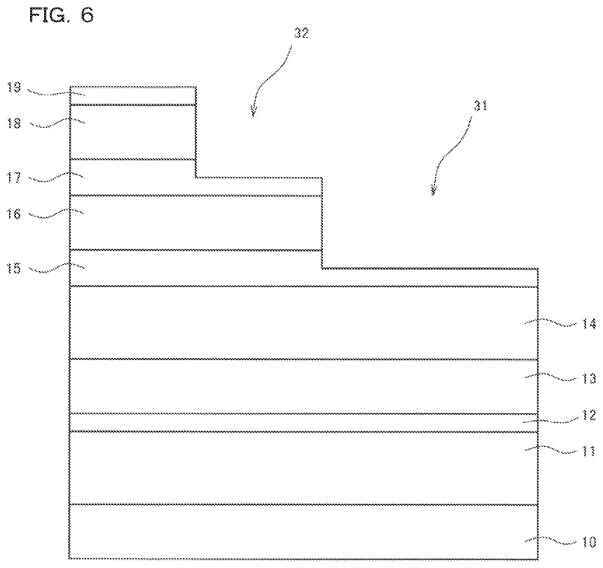

Next, a partial region of the surface of the protective layer 19 is dry-etched until reaching the second intermediate layer 17 to form the third groove 32, and dry-etched until reaching the first intermediate layer 15 to form the second groove 31 (see FIG. 6). The third groove 32 and the second groove 31 are preferably etched to an intermediate thickness between the second intermediate layer 17 and the first intermediate layer 15.

Next, the regrowth layers 20A to 20C are formed respectively on the protective layer 19, the second intermediate layer 17 exposed by the third groove 32, and the first intermediate layer 15 exposed by the second groove 31. The growth temperature is similar to that of the protective layer 19. Here, the regrowth layers 20A to 20C may be formed so as to be continuous as shown in FIG. 2. As shown in FIG. 3, the insulating film 27 may be formed on the side surfaces of the third groove 32 and the second groove 31, and the regrowth layers 20A to 20C may be selectively grown using the insulating film 27 as a mask, thereby separately forming the regrowth layers 20A to 20C.

Next, the electron block layers 21A to 21C are formed on the regrowth layers 20A to 20C. The growth temperature of the electron block layers 21A to 21C is preferably 750° C. to 1000° C. This is for the purpose of preventing thermal damage to the first active layer 14, the second active layer 16, and the third active layer 18. The temperature is more preferably 750° C. to 950° C. and still more preferably 800° C. to 900° C.

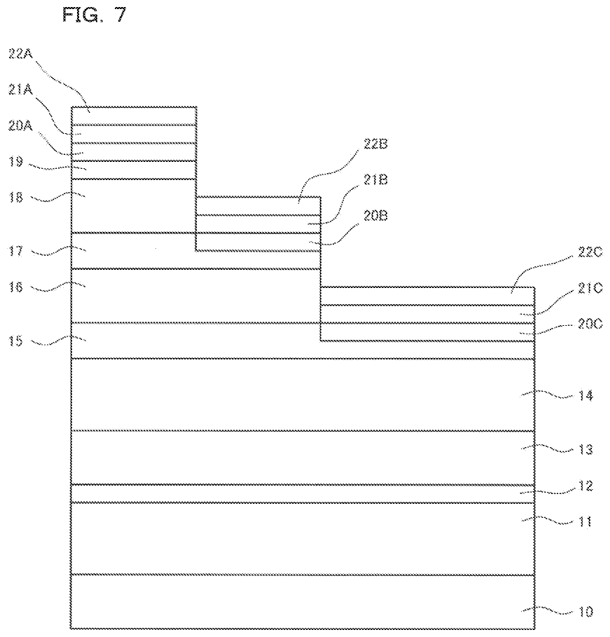

Next, the p-layers 22A to 22C are formed on the electron block layers 21A to 21C (see FIG. 7). The growth temperature of the p-layers 22A to 22C is preferably 650° C. to 1000° C. The temperature is more preferably 700° C. to 950° C. and still more preferably 750° C. to 900° C.

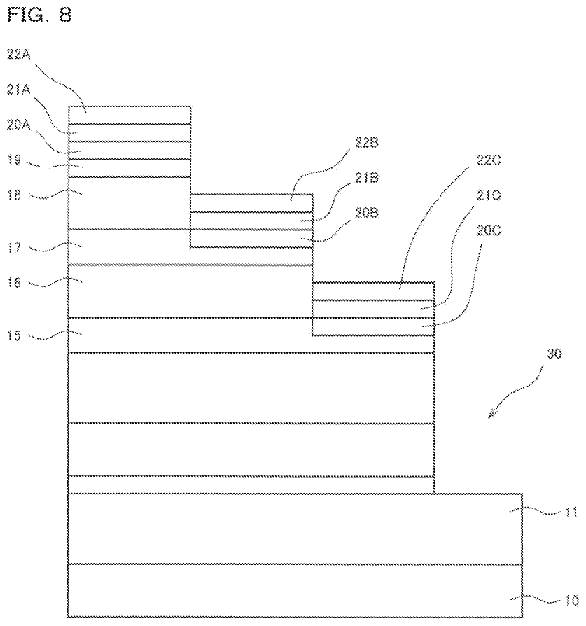

Next, a partial region of the surface of a p-layer 22 C is dry-etched until reaching the n-layer 11 to form the first groove 30 (see FIG. 8). Then, the n-electrode 23 is formed on the n-layer 11 exposed to the bottom surface of the first groove 30, and the p-electrodes 24A to 24C are formed on the p-layers 22A to 22C. As described above, the light emitting element of the first embodiment is manufactured.

### 6. Second Embodiment

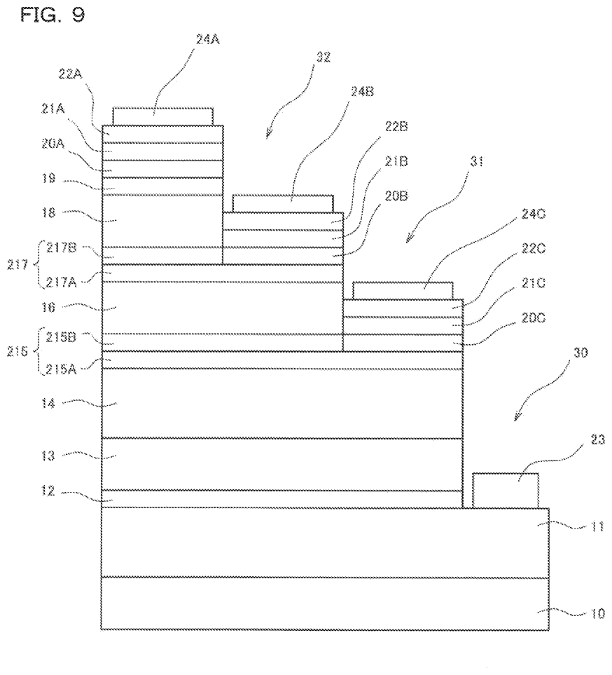

As shown in FIG. 9, the light emitting element of the second embodiment is obtained by replacing the first intermediate layer 15 and the second intermediate layer 17 with a first intermediate layer 215 and a second intermediate layer 217 in the light emitting element of the first embodiment.

The first intermediate layer 215 has a structure in which a non-doped layer 215A and an n-type layer 215B are laminated in order from the first active layer 14 side. The non-doped layer 215A and the n-type layer 215B include the same material except for impurities, and are GaN or InGaN. A material similar to that of the first intermediate layer 15 of the first embodiment is preferable. The non-doped layer 215A is non-doped, and the n-type layer 215B is Si-doped. The Si concentration of the n-type layer 215B is preferably made 1×10¹⁷ cm⁻³ to 1000×10¹⁷ cm⁻³. The thickness of the first intermediate layer 215 is preferably made the same as that of the first intermediate layer 15. That is, the thickness is preferably made 20 nm to 150 nm. The thickness of the non-doped layer 215A is preferably made 10 nm or more. This is for controllability of the etching depth and for avoiding etching damage to the first active layer 14. The thickness of the n-type layer 215B is preferably made 10 nm or more. This is because the light emission characteristics of each active layer are independently controlled. The n-type layer 215B may be modulation-doped with Si, and a partial region of the n-type layer 215B may have a non-doped region.

The second intermediate layer 217 has a structure in which a non-doped layer 217A and an n-type layer 217B are laminated in the order from the second active layer 16 side. The non-doped layer 217A and the n-type layer 217B have a similar structure to that of the non-doped layer 215A and the n-type layer 215B. That is, the non-doped layer 217A and the n-type layer 217B include the same material except for impurities, and are GaN or InGaN. The non-doped layer 217A is non-doped, and the n-type layer 217B is Si-doped. However, it is preferable to make it thinner than the first intermediate layer 215 and to make the In composition larger than that of the first intermediate layer 215. This is the same reason as in the case of the second intermediate layer 17. That is, this is because the second active layer 16 emitting green light is more prone to thermal damage than the first active layer 14 emitting blue light is, and the influence of strain at the interface becomes large.

The third groove 32 has a depth reaching the non-doped layer 217A of the second intermediate layer 217. Thus, by removing the n-type layer 217B of the second intermediate layer 17 under the p-electrode 24B, the n-type layer is prevented from being positioned on the second active layer 16, and the second active layer 16 emits light. The second groove 31 has a depth reaching the non-doped layer 215A of the first intermediate layer 215. This is also the similar reason, and by removing the n-type layer 215B of the first intermediate layer 15 under the p-electrode 24C, the n-type layer is prevented from being positioned on the first active layer 14, and the first active layer 14 emits light.

Here, the distance of the pn junction will be described. The distance of the pn junction corresponds to a film thickness that is depleted at the time of zero bias. In LED, it corresponds to the total film thickness of a non-doped or low-doped active layer sandwiched between the p-layer having a high concentration of acceptor impurities and the n-layer having a high concentration of donor impurities.

When the first intermediate layer 215 and the second intermediate layer 217 are non-doped, the distance of the pn junction (thickness of depletion layer) corresponds to a distance from the electron block layer 21A highly doped with an acceptor impurity to the n-layer 11 highly doped with a donor impurity in the region under the p-electrode 24A, that is, a film thickness including the first active layer 14, the second active layer 16, the third active layer 18, the first intermediate layer 15, and the second intermediate layer 17. Under the p-electrode 24B, it corresponds to the distance from the electron block layer 21B highly doped with the acceptor impurity to the n-layer 11, that is, the film thickness including the first active layer 14, the second active layer 16, the first intermediate layer 15, and a part of the second intermediate layer 17. Under the p-electrode 24C, it corresponds to the distance from the electron block layer 21C highly doped with the acceptor impurity to the n-layer 11, that is, the film thickness including the first active layer 14 and a part of the first intermediate layer 15.

Therefore, in these three cases, the distance of the pn junction is different, and drive voltage, current injection efficiency, and reverse current are different. When it is desired to cause the third active layer 18 to emit light by applying a voltage to the p-electrode 24A, carriers of electrons and holes are supplied to all the active layers, and there is a possibility that light is also emitted from the second active layer 16 or the first active layer 14. Similarly, when it is desired to cause the second active layer 16 to emit light by applying a voltage to the p-electrode 24B, there is a possibility that light is also emitted from the first active layer 14.

In the second embodiment, such a problem is solved by the structure of the intermediate layer. That is, in the second embodiment, the first intermediate layer 15 includes two layers of the non-doped layer 215A and the n-type layer 215B doped with donor impurities with high concentration, the second intermediate layer 17 includes two layers of the non-doped layer 217A and the n-type layer 217B doped with donor impurities with high concentration, and the n-type layers 215B and 217B are doped with Si to be n-type.

Therefore, the distance of the pn junction becomes a distance from the electron block layer 21A to the n-type layer 217B of the second intermediate layer 217 in the region under the p-electrode 24A, a distance from the electron block layer 21B to the n-type layer 215B of the first intermediate layer 215 in the region under the p-electrode 24B, and a distance from the electron block layer 21C to the n-layer 11 in the region under the p-electrode 24C. That is, the distance of the pn junction under all the electrodes does not include a plurality of active layers and corresponds to the total film thickness including one active layer and a non-doped layer among the intermediate layers.

Here, by appropriately controlling the thicknesses of the non-doped layer 215A of the first intermediate layer 215 and the non-doped layer 217A of the second intermediate layer 17, the distance of the pn junction can be made equal in these three cases. As a result, in these three cases, variations in drive voltage, current injection efficiency, and reverse current can be reduced, and uniform control becomes possible.

Furthermore, in these three cases, only one first active layer 14, one second active layer 16, and one third active layer 18 are included in the pn junction, and the n-type layer of the intermediate layer becomes a barrier layer for holes, and therefore it becomes difficult for holes to be injected into the lower active layer beyond the n-type layer of the intermediate layer. As a result, it is possible to prevent light emission from an active layer other than the active layer that is positioned in the pn junction and is intended to emit light.

### 7. Third Embodiment

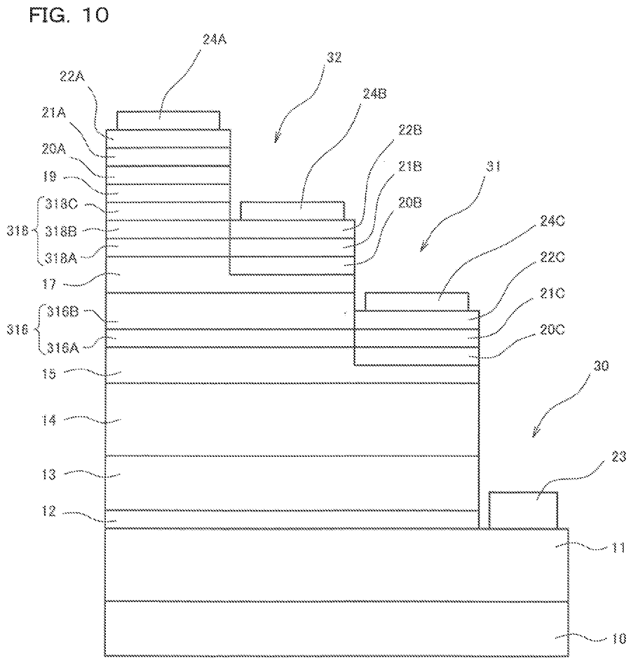

As shown in FIG. 10, the light emitting element of the third embodiment is obtained by replacing the second active layer 16 and the third active layer 18 with a second active layer 316 and a third active layer 318 in the light emitting element of the first embodiment.

The second active layer 316 has a structure in which a strain relaxation layer 316A and a quantum well structure layer (light emitting layer) 316B of a SQW or MQW structure are laminated in the order from the second intermediate layer 15 side. The quantum well structure layer 316B has a similar structure to that of the second active layer 16 of the first embodiment.

The strain relaxation layer 316A has a SQW structure in which the barrier layer, the well layer, and the barrier layer are sequentially laminated, and has a quantum well structure in which the thickness of the well layer is adjusted to be thin so as not to emit light. For example, light emission can be prevented by setting the thickness of the well layer to 1 nm or less. The barrier layer is AlGaN, and the well layer is InGaN. The wavelength corresponding to the band edge energy of the well layer of the strain relaxation layer 316A is only required to be shorter than the emission wavelength of the quantum well structure layer 316B, and is, for example, 400 nm to 460 nm when the emission wavelength of the second active layer 16 is 500 nm to 560 nm. The wavelength is preferably made shorter by 40 nm to 100 nm than the emission wavelength of the quantum well structure layer 316B. In this case, the growth temperature of the strain relaxation layer 316A is 700° C. to 800° C.

The wavelength corresponding to the band edge energy of the well layer of the strain relaxation layer 316A may be made equal to the emission wavelength of the first active layer 14. In this case, the first active layer may be grown at a similar growth temperature to that of the first active layer 14.

The band edge energy in the well layer of the strain relaxation layer 316A can be controlled by the thickness of the well layer. That is, by making the thickness of the well layer of the strain relaxation layer 316A sufficiently thin, energy of a subband in the well increases, and band edge energy becomes large. Due to this, it may be made shorter than the light emission wavelength of the quantum well structure layer 316B. The growth temperature is arbitrary, but it may be grown at a similar growth temperature to that of the quantum well structure layer 316B.

Furthermore, when the film thickness of the well layer of the strain relaxation layer 316A is thinned, the subband further increases, and the energy difference from the barrier layer becomes small. That is, the energy becomes close to the band edge energy of the barrier layer. As a result, carriers become hardly confined in the well layer of the strain relaxation layer 316A, and light becomes hardly emitted, and therefore it functions as a part of the barrier layer of the quantum well structure layer 316B, and the effect of strain relaxation is simultaneously obtained. As described above, by forming a strain relaxation layer 316A having a well layer that is worse in carrier confinement than the well layer of the quantum well structure layer 316B, the strain relaxation layer 316A that does not emit light can be formed.

In short, the material and layer configuration of the strain relaxation layer 316A is only required to be set such that the effective lattice constant of the entire strain relaxation layer 316A falls between the lattice constant of first intermediate layer 15 and the lattice constant of the quantum well structure layer 316B, and the thickness of the well layer is only required to be set such that the strain relaxation layer 316A does not emit light.

Although the strain relaxation layer 316A may have an MQW structure in which two or more pairs of barrier layers and well layers are laminated, it is preferable to have a SQW structure because the second active layer 316 becomes thick.

By providing the strain relaxation layer 316A as described above, it is possible to relax the strain of the quantum well structure layer 316B laminated thereon, and it is possible to improve the crystal quality of the well layer of the quantum well structure layer 316B.

The ratio of the thickness of the first active layer 14 to the thickness of the second active layer 316 is preferably set to 30% or less. Strain of the quantum well structure layer 316B can be relaxed more efficiently, and the distance of the pn junction becomes constant under each of the p-electrodes 24A to 24C, and device characteristics under each of the p-electrodes 24A to 24C can be made uniform.

The third active layer 318 is structured so that a first strain relaxation layer 318A, a second strain relaxation layer 318B, and a quantum well structure layer 318C of a SQW or MQW structure are y laminated in the order from the second intermediate layer 17 side. The quantum well structure layer 318C has a similar structure to that of the third active layer 18 of the first embodiment.

The first strain relaxation layer 318A has a similar structure to that of the strain relaxation layer 316A of the second active layer 316. The wavelength corresponding to the band edge energy of the well layer of the first strain relaxation layer 318A is only required to be shorter than the emission wavelength of the quantum well structure layer 316B, and is, for example, 400 nm to 460 nm.

In the second strain relaxation layer 318B, the wavelength corresponding to the band edge energy of the well layer of the second strain relaxation layer 318B is shorter than the emission wavelength of the quantum well structure layer 318C and longer than the wavelength corresponding to the band edge energy of the well layer of the first strain relaxation layer 318A. For example, it is 510 nm to 570 nm. The others are similar to the first strain relaxation layer 318A.

The difference between the wavelength corresponding to the band edge energy of the well layer of the first strain relaxation layer 318A and the wavelength corresponding to the band edge energy of the well layer of the second strain relaxation layer 318B and the difference between the wavelength corresponding to the band edge energy of the well layer of the second strain relaxation layer 318B and the emission wavelength of the quantum well structure layer 318C are preferably made 40 nm to 100 nm.

The ratio of the thickness of the first active layer 14 to the thickness of the third active layer 318 and the ratio of the thickness of the second active layer 316 to the thickness of the third active layer 318 are preferably set to 30% or less. Strain of the quantum well structure layer 318C can be relaxed more efficiently, and the distance of the pn junction becomes constant under each of the p-electrodes 24A to 24C, and device characteristics under each of the p-electrodes 24A to 24C can be made uniform.

By providing the first strain relaxation layer 318A and the second strain relaxation layer 318B in this manner, it is possible to relax the strain in stages, and it is possible to effectively relax the strain of the quantum well structure layer 318C laminated thereon. As a result, it is possible to improve the quality of the well layer of the quantum well structure layer 318C.

In the third active layer 318, although the strain is relaxed in two stages by the first strain relaxation layer 318A and the second strain relaxation layer 318B, but the strain may be relaxed in three or more stages by providing three or more strain relaxation layers. Also in the second active layer 316, a plurality of the strain relaxation layers 316A may be provided to relax strain in stages.

A strain relaxation layer may be similarly provided in the first active layer 14. In this case, the growth temperature of the strain relaxation layer is, for example, 800° C. to 900° C.

### 8. Modifications of First to Third Embodiments

The light emitting element of the present embodiment has the three active layers of the first active layer 14, the second active layer 16, and the third active layer 18, but can also be applied to a structure having two or more active layers having different emission wavelengths from one another. The emission color is not limited to blue, green, and red, and may be any color as long as they have different emission wavelengths.

The light emitting element of the present embodiment is preferably PWM-driven by a PWM circuit to control light emission. The light intensity can be easily controlled by a pulse width and a pulse period, and a wavelength shift due to a difference in a drive current can also be curtailed.

### 9. Experimental Results

Next, experimental results related to the present embodiment will be described.

9-1. Experiment 1

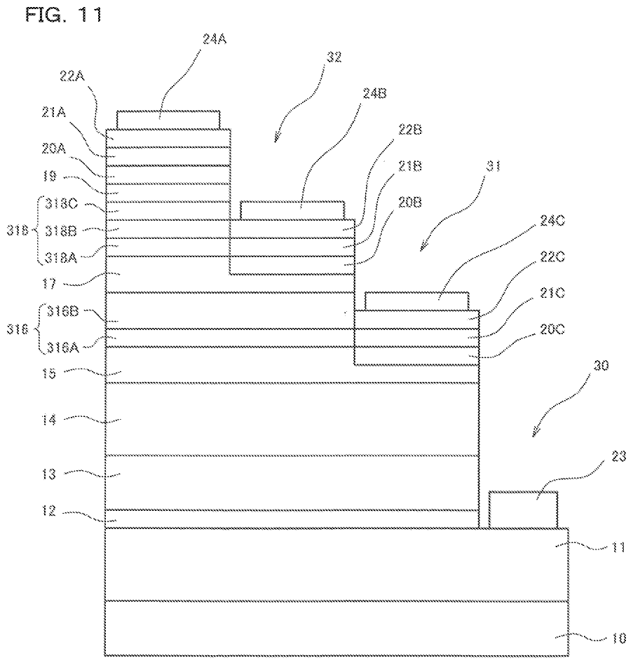

A light emitting element was produced in which the second intermediate layer 17 and the third active layer 18 were omitted from the light emitting element of the first embodiment, the regrowth layer 20B, the electron block layer 21B, the p-layer 22B, and the p-electrode 24B were further omitted, the first intermediate layer 15 was replaced with the first intermediate layer 215 of the second embodiment, and the second active layer 16 was replaced with the second active layer 316 of the third embodiment (see FIG. 11, hereinafter referred to as light emitting element of Experimental Example 1). The first intermediate layer 215 was InGaN with In composition of 5%. The wavelength corresponding to the band edge energy of the well layer in the strain relaxation layer 316A of the second active layer 316 was made similar to the emission wavelength of the first active layer 14, and had the SQW structure.

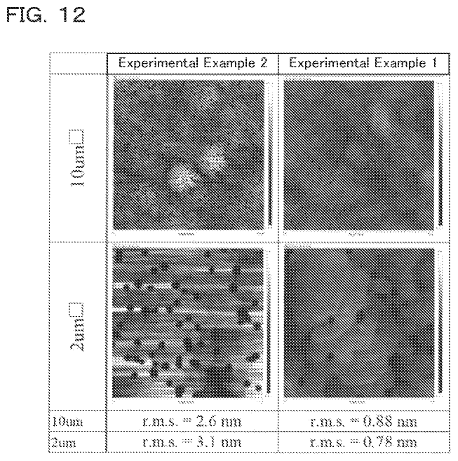

FIG. 12 is an AFM image obtained by photographing the surface of the second active layer 316 of the light emitting element of Experimental Example 1. In FIG. 12, the upper part shows a range of 10 μm square, and the lower part shows a range of 2 μm square. For comparison, a case (Experimental Example 2) where the first intermediate layer 215 was GaN, and the others were made similar to those in Experimental Example 2 will also be described. As in FIG. 12, in Experimental Example 1, the density of pits was lower than that in Experiment Example 2. A surface flatness RMS in the range of 10 μm square was 0.88 nm in Experimental Example 1 and 2.6 nm in Experimental Example 2, and the surface flatness RMS in the range of 2 μm square was 0.78 nm in Experimental Example 1 and 3.1 nm in Experimental Example 2. In each case, those in Experimental Example 1 was smaller than those in Experimental Example 2. As a result, it is found that In in the first intermediate layer 215 acted as a surfactant, and the surface flatness of the first intermediate layer 215 was improved, whereby the surface flatness and crystal quality of the second active layer 316 thereon were also improved.

FIG. 9 is a graph showing the relationship between the drive current and the external quantum efficiency for the light emitting elements of Experimental Examples 1 and 2. The external quantum efficiency is that in a case where the second active layer 316 was caused to emit light by applying a voltage to the p-electrode 24B. As in FIG. 9, Experimental Example 1 was higher in external quantum efficiency than Experimental Example 2. This indicates that the external quantum efficiency was improved by improving the crystal quality of the second active layer 316.

### 9-2. Experiment 2

For the light emitting element (light emitting element shown in FIG. 1, hereinafter referred to as light emitting element of Experimental Example 3) of the first embodiment having the emission wavelength of the first active layer 14 of 430 nm, the emission wavelength of the second active layer 16 of 520 nm, and the emission wavelength of the third active layer 18 of 630 nm, a current was injected to the p-electrode 24A, and emission spectra thereof were measured. The Si concentrations of the n-type layer 215B and the n-type layer 217B were three patterns of 1×10¹⁸ cm⁻³, 2×10¹⁸ cm⁻³, and 3×10¹⁸ cm⁻³. For comparison, the emission spectra were also measured in the case were the n-type layer 215B and the n-type layer 217B were replaced with a non-doped layer.

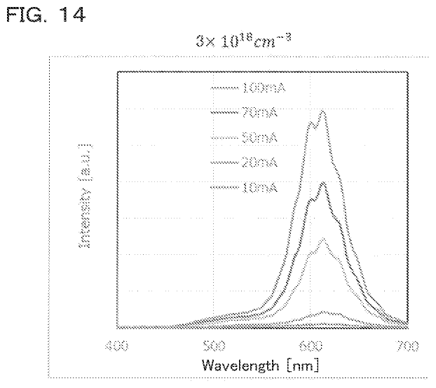

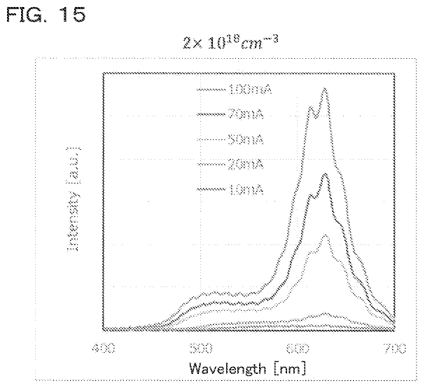

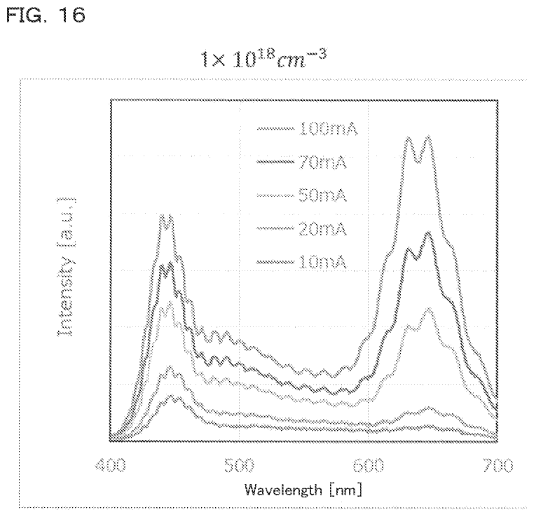

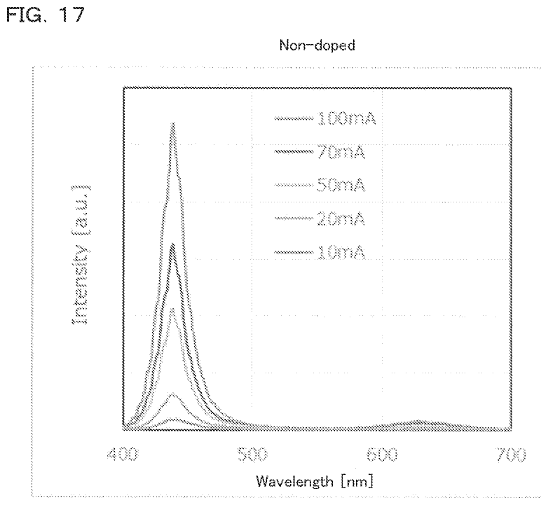

FIGS. 14 to 17 are graphs showing emission spectra, where FIG. 14 shows a Si concentration of 3×10¹⁸ cm⁻³, FIG. 15 shows a Si concentration of 2×10¹⁸ cm⁻³, FIG. 16 shows a Si concentration of 1×10¹⁸ cm⁻³, and FIG. 17 shows the non-doped. As in FIG. 17, in the case of non-doping, not only red light emission of the third active layer 18 but also blue light emission of the first active layer 14 occurred, and it was found that the red light emission was weak and the blue light emission was strong. On the other hand, as in FIGS. 14 to 16, in the case of Si doping, red light emission also became as strong as or stronger than blue light emission, and the higher the Si concentration was, the lower the intensity of blue light emission was. Although green light emission also slightly appeared in place of a decrease in intensity of blue light emission of the second active layer 16, the intensity of green light emission also decreased when the Si concentration became sufficiently high as in FIG. 14. As a result, it was found that by introducing the Si-doped n-type layer 215B and n-type layer 217B into the first intermediate layer 15 and the second intermediate layer 17, light emission from active layers (first active layer 14 and second active layer 16) other than the third active layer 18 which is an active layer expected to emit light, can be curtailed.

9-3. Experiment 3

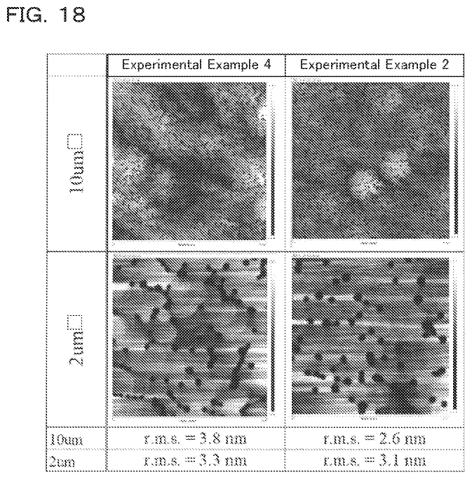

FIG. 18 is an AFM image obtained by photographing the surface of the quantum well structure layer 316C of the light emitting elements of Experimental Examples 2 and 4. Experimental Example 4 is related to a case where the second active layer 316 was not provided with the strain relaxation layer 316A in Experimental Example 2. In FIG. 16, the upper part shows a range of 10 μm square, and the lower part shows a range of 2 μm square. As in FIG. 18, the surface flatness RMS in the range of 10 μm square was 2.6 nm in Experimental Example 2 and 3.8 nm Experimental Example 4, and the surface flatness RMS in the range of 2 μm square was 3.1 nm in Experimental Example 2 and 3.3 nm in Experimental Example 4. In each case, those in Experimental Example 2 was smaller than those in Experimental Example 4. That is, the surface flatness was improved. As a result, it is found that by introducing the strain relaxation layer 316A to the second active layer 316, the strain of the quantum well structure layer 316B thereon was relaxed and the surface flatness and the crystal quality were improved.

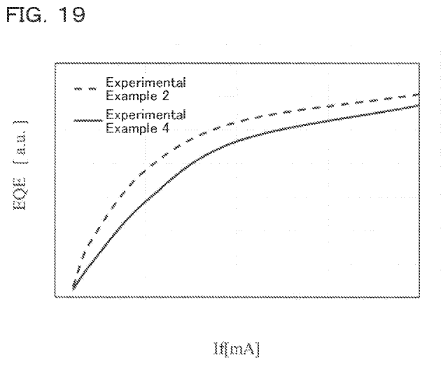

FIG. 19 is a graph showing the relationship between the drive current and the external quantum efficiency for the light emitting elements of Experimental Examples 2 and 4. The external quantum efficiency is that in a case where the second active layer 316 was caused to emit light by applying a voltage to the p-electrode 24A. As in FIG. 19, Experimental Example 2 was higher in external quantum efficiency than Experimental Example 4. This indicates that the strain of the second active layer 316 was relaxed, and the surface flatness and the crystal quality were improved, so that the external quantum efficiency was improved.

### 10. Fourth Embodiment

10-1. Configuration of Light Emitting Element

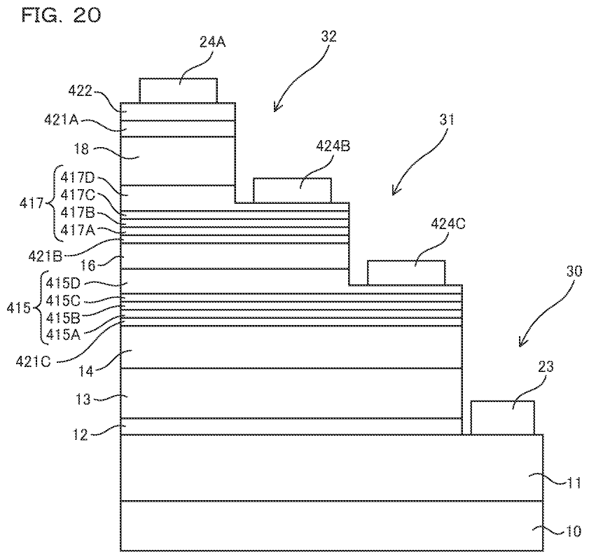

FIG. 20 is a view showing the configuration of the light emitting element in the fourth embodiment, and is a cross-sectional view taken along a plane perpendicular to a substrate main surface. As shown in FIG. 20, the light emitting element in the fourth embodiment was obtained by changing a part of the configuration of the light emitting element in the first embodiment as follows. Similar components to those of the first embodiment are denoted by the same reference numerals, and the description thereof will be omitted.

As in FIG. 20, the first intermediate layer 15 and the second intermediate layer 17 are replaced with a first intermediate layer 415 and a second intermediate layer 417. The protective layer 19, the regrowth layers 20A to 20C, the electron block layers 21A to 21C, and the p-layers 22A to 22C are omitted, an electron block layer 421A and a p-layer 422 are provided on the third active layer 18, and the p-electrode 24A is provided on a p-layer 422. That is, the light emitting element of the fourth embodiment has no regrowth layer. A first electrode 424B is provided on the first intermediate layer 415 exposed to the bottom surface of the second groove 31, and a second electrode 424C is provided on the second intermediate layer 417 exposed to the bottom surface of the third groove 32. Electron block layers 421B and 421C are inserted between the second active layer 16 and the second intermediate layer 17 and between the first active layer 14 and the first intermediate layer 15, respectively.

The electron block layer 421C is a p-type layer provided on the first active layer 14, and is positioned between the first active layer 14 and the first intermediate layer 15. The electron block layer 421C is similar to the electron block layers 21A to 21C except that the electron block layer is continuously grown on not the regrowth layer but the first active layer 14.

The first intermediate layer 415 has a structure in which a first layer 415A, a second layer 415B, a third layer 415C, and a fourth layer 415D are laminated in the order from the first active layer 14 side, and the fourth layer 415D is exposed to the bottom surface of the second groove 31. The second layer 415B and the third layer 415C form a tunnel junction structure. Thus, the first intermediate layer 415 has the tunnel junction function in addition to the similar functions to those of the first intermediate layer 15 of the first embodiment.

The first layer 415A is a semiconductor layer provided on the electron block layer 421C. In order to cause the first active layer 14 to efficiently emit light, the first active layer 14 is preferably sandwiched between a p-type layer and an n-type layer, and the first layer 415A is provided as a contact layer of the p-type.

The material of the first layer 415A is similar to that of the first intermediate layer 15 in the first embodiment except for impurities. That is, it is a group-III nitride semiconductor containing In, and is preferably InGaN, for example. The roughness of the surface of the first intermediate layer 415 can be reduced by the surfactant effect by In, so that the surface flatness can be improved. In addition, lattice strain can be relaxed. The In composition of the first intermediate layer 415 is only required to be set so as to have a band gap that does not absorb light emitted from the first active layer 14, the second active layer 16, and the third active layer 18.

The In composition of the first layer 415A is preferably 10% or less, more preferably 5% or less, and still more preferably 2% or less. The In composition that is more than 10% causes roughness of the surface of the first intermediate layer 415. In is arbitrary as long as it is larger than 0%, and may be at a doping level (level at which a mixed crystal is not formed). For example, GaN having an In concentration of 1×10¹⁴ cm⁻³ or more and 1×10 22 cm⁻³ or less is used.

The first layer 415A is a p-type semiconductor doped with Mg, which is a p-type impurity. For example, the Mg concentration may be 1×10¹⁸ cm⁻³ to 1×10²⁰ cm⁻³, preferably 5×10¹⁸ cm⁻³ to 1×10²⁰ cm⁻³, more preferably 1×10¹⁹ cm⁻³ to 1×10²⁰ cm⁻³. Although it may be non-doped, it is preferably doped with Mg as described above. For the first layer 415A, polarization doping that provides a gradient in In composition in the thickness direction may be used. In this case, it may be non-doped. The third layer 415C may be doped with Mg by Mg diffusion from the electron block layer 421C, which is a layer under the first layer 415A. In this case, the Mg concentration of the electron block layer 421C is preferably in a range of 1×10¹⁹ cm⁻³ to 1×10²¹ cm⁻³.

The thickness of the first layer 415A is preferably made 10 nm to 300 nm. The thickness thicker than 300 nm can cause roughness of the surface of the first intermediate layer 415. When the thickness is thinner than 10 nm, there is a possibility that the light emission efficiency of the first active layer 14 cannot be sufficiently enhanced. The thickness is more preferably 20 nm to 200 nm and still more preferably 30 nm to 100 nm.

The second layer 415B is a semiconductor layer provided on the first layer 415A. The tunnel junction structure is formed by laminating the second layer 415B and the third layer 415C.

The material of the second layer 415B is similar to that of the first layer 415A except for impurities. The In composition of the second layer 415B may be different from the In composition of the first layer 415A or the fourth layer 415D, and in that case, it is preferably higher than the In composition of the first layer 415A or the fourth layer 415D. The tunnel probability by the tunnel junction structure can be further increased. The preferred In composition range of the second layer 415B is similar to that of the first layer 415A.

The second layer 415B is a p-type semiconductor doped with Mg, which is a p-type impurity. The Mg concentration is 1×10²⁰ cm⁻³ to 1×10²¹ cm⁻³. The Mg concentration of the second layer 415B is higher than the Mg concentration of the first layer 415A.

The thickness of the second layer 415B is 5 nm to 50 nm. Within this range, the tunnel probability of the tunnel junction structure can be sufficiently enhanced. The thickness is more preferably 5 nm to 35 nm and still more preferably 5 nm to 20 nm. The thickness of the second layer 415B is preferably thinner than that of the first layer 415A.

The third layer 415C is a semiconductor layer provided on the second layer 415B. The tunnel junction structure is formed by laminating the second layer 415B and the third layer 415C. With this tunnel junction structure, a current flows from the n-type third layer 415C to the p-type second layer 415B by the tunnel effect, and a hole is supplied to the first active layer 14.

The material of the third layer 415C is similar to that of the first layer 415A except for impurities. The In composition of the third layer 415C may be different from the In composition of the first layer 415A or the fourth layer 415D, and in that case, it is preferably higher than the In composition of the first layer 415A or the fourth layer 415D. The tunnel probability by the tunnel junction structure can be further increased. The In composition of the third layer 415C may be different from the In composition of the second layer 415B. In this case, the In composition of the third layer 415C is preferably lower than the In composition of the second layer 415B. The preferred In composition range of the third layer 415C is similar to that of the first layer 415A.

The third layer 415C is an n-type semiconductor doped with Si, which is an n-type impurity. The Si concentration is 1×10²⁰ cm⁻³ to 1×10²¹ cm⁻³.

In the vicinity of a junction interface between the second layer 415B and the third layer 415C, a layer co-doped with Si and Mg may exist intentionally or naturally. Since Mg tends to remain in a furnace due to a memory effect, the third layer 415C and the fourth layer 415D may be doped with Mg. However, the Mg concentrations of the third layer 415C and the fourth layer 415D need to become lower than the respective Si concentrations.

The thickness of the third layer 415C is 1 nm to 30 nm. Within this range, the tunnel probability of the tunnel junction structure can be sufficiently enhanced. The thickness is more preferably 2 nm to 25 nm and still more preferably 5 nm to 20 nm. The thickness of the third layer 415C is preferably thinner than that of the fourth layer 415D.

As described above, since the second layer 415B and the third layer 415C forming the tunnel junction structure contain In, the band gap becomes small and the tunnel probability becomes high. In a range where tunnel junction is provided between the second layer 415B and the third layer 415C, a layer may be further provided between the second layer 415B and the third layer 415C. For example, a buffer layer for preventing Mg of the second layer 415B from diffusing to the third layer 415C may be provided.

The fourth layer 415D is a semiconductor layer provided on the third layer 415C. In order to cause the second active layer 16 to efficiently emit light, the second active layer 16 is preferably sandwiched between a p-type layer and an n-type layer, and the fourth layer 415D is provided as a contact layer of the n-type. The fourth layer 415D is a layer so as not to reach the third layer 415C and to be exposed when the second groove 31 is formed.

The material of the fourth layer 415D is similar to that of the first intermediate layer 15 in the first embodiment except for impurities. The In composition may be different from that of the first layer 415A.

The fourth layer 415D is an n-type semiconductor doped with Si, which is an n-type impurity. For example, the Si concentration may be 1×10¹⁷ cm⁻³ to 1000×10²⁰ cm⁻³, preferably 1×10¹⁸ cm⁻³ to 1×10¹⁹ cm⁻³, more preferably 2×10¹⁸ cm⁻³ to 8×10¹⁸ cm⁻³. The Si concentration of the third layer 415C is higher than the impurity concentration of the fourth layer 415D.

The thickness of the fourth layer 415D is preferably made 10 nm to 500 nm. The thickness thicker than 500 nm can cause roughness of the surface of the first intermediate layer 415. When the thickness is thinner than 10 nm, there is a possibility that the light emission efficiency of the second active layer 16 cannot be sufficiently enhanced. There is a possibility that it becomes difficult to control the depth of the second groove 31 to be in the fourth layer 415D when the second groove 31 is formed. The thickness is more preferably 10 nm to 200 nm and still more preferably 10 nm to 100 nm. The thickness of the fourth layer 415D may be different from the thickness of the first layer 415A.

The electron block layer 421B is a p-type layer provided on the second active layer 16, and is positioned between the second active layer 16 and the second intermediate layer 17. The electron block layer 421B is similar to the electron block layers 21A to 21C except that the electron block layer is continuously grown on not the regrowth layer but the second active layer 16.

The second intermediate layer 417 has a structure in which a first layer 417A, a second layer 417B, a third layer 417C, and a fourth layer 417D are laminated in order from the second active layer 16 side, and the fourth layer 417D is exposed to the bottom surface of the third groove 32. The second layer 417B and the third layer 417C form a tunnel junction structure. Thus, the second intermediate layer 417 has the tunnel junction function in addition to the similar functions to those of the second intermediate layer 17 of the first embodiment.

The first layer 417A, the second layer 417B, the third layer 417C, and the fourth layer 417D are similar to the first layer 415A, the second layer 415B, the third layer 415C, and the fourth layer 415D of the first intermediate layer 415, respectively. The tunnel junction structure is formed by laminating the second layer 417B and the third layer 417C, a current flows from the n-type third layer 417C to the p-type second layer 417B by the tunnel effect, and a hole is supplied to the second active layer 16.

Since all layers of the first intermediate layer 415 and the second intermediate layer 417 include InGaN, the similar effects to those of the first intermediate layer 15 and the second intermediate layer 17 of the first embodiment can be obtained. That is, the surface flatness can be improved, and the lattice strain can be relaxed.

The average In composition of the first intermediate layer 415 and the average In composition of the second intermediate layer 417 may be different. The average In composition of the second intermediate layer 417 is preferably higher than the average In composition of the first intermediate layer 415.

The electron block layer 421A is a p-type layer provided on the third active layer 18. The electron block layer 421A is similar to the electron block layers 21A to 21C except that the electron block layer is continuously grown on not the regrowth layer but the third active layer 18.

The p-layer 422 is a layer provided on the electron block layer 421A. The p-layer 422 is similar to the p-layer 22A except that the p-layer is continuously grown on not the regrowth layer but the electron block layer 421A.

In place of the p-layer 422, a tunnel junction structure such as the second layer 415B and the third layer 415C or the second layer 417B and the third layer 417C may be used. In this case, in place of the p-electrode 24A, an electrode using an n-contact material can be used, and the same material as those of the first electrode 424B and the second electrode 424C can be used. Therefore, all electrodes can be formed in the same process.

The first electrode 424B is provided on the fourth layer 417D of the second intermediate layer 417 exposed to the bottom surface of the third groove 32. The second electrode 424C is provided on the fourth layer 415D of the first intermediate layer 415 exposed to the bottom surface of the second groove 31. The first electrode 424B and the second electrode 424C serve as both an anode electrode and a cathode electrode. The first electrode 424B and the second electrode 424C are only required to include a material capable of ohmic contact with n-type InGaN, and for example, Ti/Al can be used. The material may be the same as that of the n-electrode 23.

In the light emitting element of the fourth embodiment, the second active layer 16 and the third active layer 18 may be replaced with the second active layer 316 and the third active layer 318 of the third embodiment, respectively. In this case, the strain relaxation layer 316A of the second active layer 316 functions as a buffer layer against Mg diffusion from the first intermediate layer 415 to the quantum well structure layer 316B. The first strain relaxation layer 318A and the second strain relaxation layer 318B of the third active layer 318 function as buffer layers against Mg diffusion from the second intermediate layer 417 to the quantum well structure layer 318C. Therefore, a decrease in light emission efficiency can be curtailed.

Other than that, various modifications described in the first to third embodiments can also be applied to the fourth embodiment. For example, the first embodiment and the fourth embodiment may be combined as follows. In the fourth embodiment, the second intermediate layer 417 may have a tunnel junction structure as it is, and the first intermediate layer 415 may have a configuration in which a regrowth layer 20C, an electron block layer 21C, and the p-layer 22C are provided as in the first embodiment in place of the first intermediate layer 15 of the first embodiment.

Such a configuration has the following advantages. The first active layer 14 emitting blue light has high light emission efficiency, and there is no significant problem even if the light emission efficiency decreases due to regrowth. On the other hand, the second active layer 16 emitting green light has low light emission efficiency, and it is desirable to avoid a decrease in light emission efficiency due to regrowth as much as possible. Therefore, when the element region for blue light emission is formed by groove formation and regrowth as in the first embodiment, and the element region for green light emission is formed using the tunnel junction structure as in the fourth embodiment, it is possible to reduce variations in light emission efficiency of blue, green, and red.

10-2. Operation of Light Emitting Element

The operation of the light emitting element of the fourth embodiment will be described. The light emitting element of the fourth embodiment can emit red light from the third active layer 18 by applying a voltage between the p-electrode 24A and the first electrode 424B. Green light can be emitted from the second active layer 16 by applying a voltage between the first electrode 424B and the second electrode 424C. Blue light can be emitted from the first active layer 14 by applying a voltage between the second electrode 424C and the n-electrode 23.

Two or more of blue, green, and red can be simultaneously emitted. Specifically, a voltage is applied as follows. When all of blue, green, and red are emitted, a voltage is applied between the p-electrode 24A and the n-electrode 23. When green and red are simultaneously emitted, a voltage is applied between the p-electrode 24A and the second electrode 424C. When blue and green are simultaneously emitted, a voltage is applied between the first electrode 424B and the n-electrode 23. When blue and red are simultaneously emitted, a voltage is applied between the p-electrode 24A and the first electrode 424B and between the second electrode 424C and the n-electrode 23.

As described above, the light emitting element of the fourth embodiment can control blue, green, and red emission by selection of an electrode applied with the voltage, and the light emitting element can be used as one pixel of display.

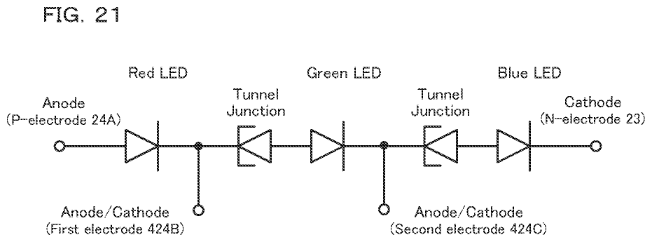

FIG. 21 shows an equivalent circuit of the light emitting element of the fourth embodiment. The light emitting element of the fourth embodiment is equivalent to a configuration in which a red LED, a first tunnel junction (tunnel diode in reverse order), a green LED, a second tunnel junction, and a blue LED are connected in cascade, and an electrode is drawn out from a connection portion between the red LED and the first tunnel junction and a connection portion between the green LED and the second tunnel junction. Similarly to the light emitting element of the first embodiment, the light emitting element of the fourth embodiment also has a structure in which blue, green, and red LEDs are formed in one element, and full color light emission can be achieved by one element.

10-3. Manufacturing Method of Light Emitting Element

Next, a manufacturing process of the light emitting element of the fourth embodiment will be described.

First, as in the first embodiment, the substrate 10 is prepared and subjected to heat treatment. Thereafter, by the MOCVD method, the buffer layer, the n-layer 11, the ESD layer 12, the underlayer 13, the first active layer 14, the electron block layer 421C, the first intermediate layer 415, the second active layer 16, the electron block layer 421B, the second intermediate layer 417, the third active layer 18, the electron block layer 421A, and the p-layer 422 are formed on the substrate 10 in the order from the substrate side.

Here, the growth temperature of the first intermediate layer 415 and the second intermediate layer 417 is in the similar range to that of the first intermediate layer 15 and the second intermediate layer 17 of the first embodiment. The growth temperature of the second intermediate layer 417 is preferably made lower than the growth temperature of the first intermediate layer 415. This is because the second active layer 16 emitting green light is more prone to thermal damage than the first active layer 14 emitting blue light is, and the influence of strain at the interface becomes large.

In the formation of the first intermediate layer 415, the growth temperature of the second layer 415B and the third layer 415C is preferably made lower than the growth temperature of the first layer 415A and the fourth layer 415D. This is to enhance the crystallinity and further enhance the tunnel effect in the tunnel junction. Also in the formation of the second intermediate layer 417, the growth temperatures of the second layer 417B and the third layer 417C are preferably made lower than the growth temperatures of the first layer 417A and the fourth layer 417D.

Next, a partial region of the surface of the p-layer 422 is dry-etched until reaching the fourth layer 417D of the second intermediate layer 417 to form the third groove 32, dry-etched until reaching the fourth layer 415D of the first intermediate layer 415 to form the second groove 31, and dry-etched until reaching the n-layer 11 to form the first groove 30.

Next, the n-electrode 23 is formed on the n-layer 11 exposed to the bottom surface of the first groove 30, the p-electrode 24A is formed on the p-layer 422, the first electrode 424B is formed on the bottom surface of the third groove 32, and the second electrode 424C is formed on the bottom surface of the second groove 31. When the first electrode 424B and the second electrode 424C include the same material as that of the n-electrode 23, they can be formed simultaneously in the same process as the n-electrode 23. As described above, the light emitting element of the fourth embodiment is manufactured.

As described above, since the first intermediate layer 415 and the second intermediate layer 417 are provided with the tunnel junction structure, it is not necessary to provide the light emitting element in the fourth embodiment with the electron block layer or the regrowth layer of the p-layer. Since etching damage, impurity contamination due to atmospheric exposure, and thermal damage due to regrowth occur at the regrown interface, the presence of the regrown interface between pn may deteriorate device characteristics. However, since the light emitting element of the fourth embodiment does not have a regrowth layer and does not have a regrown interface between pn, such a problem does not occur.

In the first to fourth embodiments, InGaN is used as a well layer in the quantum well structure layers 318C of the third active layer 18 and the third active layer 318, but a europium (Eu)-doped group-III nitride semiconductor, particularly GaN can also be used. Also in this case, red light can be emitted, and the emission wavelength is about 620 nm. When Eu-doped GaN is used, strain relaxation of the active layer is no longer required, and thus the first strain relaxation layer 318A and the second strain relaxation layer 318B as the third active layer 318 need not be provided. When Eu-doped GaN is used for the well layer, the barrier layer is, for example, AlGaN.

Similarly, a praseodymium (Pr)-doped group-III nitride semiconductor, particularly GaN may be used. It can be used as a red light emitting material.

As the well layer in the quantum well structure layers 316B of the second active layer 16 and the second active layer 316, a terbium (Tb)-doped group-III nitride semiconductor, particularly GaN can also be used. Also in this case, green light can be emitted.

As the well layer in the first active layer 14, a thulium (Tm)-doped group-III nitride semiconductor, particularly GaN can also be used. Also in this case, blue light can be emitted.

### 11. Fifth Embodiment

11-1. Configuration of Light Emitting Element

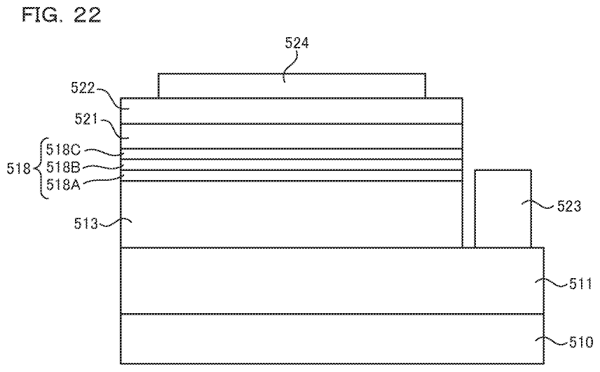

FIG. 22 is a view showing the configuration of the light emitting element in the fifth embodiment, and is a cross-sectional view taken along a plane perpendicular to a substrate main surface. The light emitting element in the fifth embodiment has emission colors from yellow to red, and includes a substrate 510, an n-layer 511, an underlayer 513, an active layer 518, an electron block layer 521, a p-layer 522, an n-electrode 523, and a p-electrode 524 as shown in FIG. 22.

The substrate 510, the n-layer 511, and the underlayer 513 are similar to the substrate 10, the n-layer 11, and the underlayer 13 in the first embodiment, respectively. The ESD layer 12 may be provided between the n-layer 511 and the underlayer 513.

The underlayer 513 is preferably made a laminate of a superlattice structure layer and a high-concentration n-type GaN layer. The superlattice structure layer is preferably formed by alternately laminating n-type InGaN and n-type GaN, and the number of pairs is, for example, 3 to 30. The Si concentration is, for example, 1×10¹⁷ cm⁻³ to 1×10¹⁹ cm⁻³. The Si concentration of the high-concentration n-type GaN layer on the superlattice structure layer is preferably 1×10¹⁸ cm⁻³ to 1×10¹⁹ cm⁻³. The high-concentration n-type GaN layer is preferably in contact with the active layer 518.

The active layer 518 is a layer provided on the underlayer 513. The active layer 518 is structured so that a first strain relaxation layer 518A, a second strain relaxation layer 518B, and a quantum well structure layer 518C of a SQW or MQW structure are laminated in the order from the underlayer 513 side.

The first strain relaxation layer 518A and the second strain relaxation layer 518B are similar to the first strain relaxation layer 318A and the second strain relaxation layer 318B in the third active layer 318 of the third embodiment, respectively. As in the third embodiment, by providing the first strain relaxation layer 518A and the second strain relaxation layer 518B, it is possible to relax the strain in stages, and it is possible to effectively relax the strain of the quantum well structure layer 518C laminated thereon. As a result, it is possible to improve the quality of the well layer of the quantum well structure layer 518C. The first strain relaxation layer 518A and the second strain relaxation layer 518B are preferably a SQW structure.

Various modifications of the first strain relaxation layer 318A and the second strain relaxation layer 318B in the third embodiment can be similarly applied to the first strain relaxation layer 518A and the second strain relaxation layer 518B.

The quantum well structure layer 518C is a light emitting layer having a SQW or MQW structure provided on the second strain relaxation layer 518B. The emission wavelength is from yellow to red, and is 560 nm to 700 nm. The third active layer 18 has a structure in which 1 to 7 pairs of a well layer including InGaN and a barrier layer including InGaN having an In composition lower than that of the well layer are alternately laminated. The number of pairs is more preferably 1 to 5 and still more preferably 1 to 3. The number of pairs is preferably equal to or smaller than the number of pairs of the second active layer 16, and more preferably smaller. A SQW structure is most preferable. The well layer of the quantum well structure layer 518C is InGaN having In composition of 35% or more.

The electron block layer 521 is a layer provided on the active layer 518. The electron block layer 521 is similar to the electron block layer 421A of the fourth embodiment.

The p-layer 522 is a layer provided on the electron block layer 521. The p-layer 522 is similar to the p-layer 422 of the fourth embodiment.

A part of the p-layer 522 is etched to provide a groove reaching the n-layer 11, and the n-electrode 523 is provided on the n-layer 11 exposed to the bottom surface of the groove. The material of the n-electrode 523 is similar to that of the n-electrode 23. The p-electrode 524 is provided on the p-layer 522. The material of the p-electrode 524 is similar to that of the p-electrodes 24A to 24C.

11-2. Manufacturing Method of Light Emitting Element

Next, a manufacturing process of the light emitting element of the fifth embodiment will be described.

First, as in the first embodiment, the substrate 10 is prepared and subjected to heat treatment. Thereafter, by the MOCVD method, the buffer layer, the n-layer 11, the underlayer 13, the active layer 518, the electron block layer 521, and the p-layer 522 are formed on the substrate 10 in the order from the substrate 10 side. A formation method of the quantum well structure layer 518C will be described in detail later. The source gas used in the MOCVD method is, for example, as follows. Trimethylgallium (TMG) or triethylgallium (TEG) is used as Ga source gas, trimethylindium (TMI) is used as In source gas, trimethylaluminum (TMA) is used as Al source gas, ammonia is used as N source gas, silane is used as Si dopant gas, cyclopentadienyl (bis) magnesium is used as Mg dopant gas, and hydrogen or nitrogen is used as carrier gas.

The growth temperature of the electron block layer 521 and the p-layer 522 is preferably made 935° C. or lower. This is for the purpose of reducing thermal damage to the active layer 518 and reducing a decrease in light emission efficiency. The lower limit of the growth temperature is, for example, 600° C. The temperature is more preferably 650° C. to 900° C. The growth temperature of the p-layer 522 is preferably made higher than the growth temperature of the electron block layer 521.

Next, a predetermined region of the p-layer 522 is dry-etched to form a groove reaching the n-layer 11, and the n-electrode 523 is formed on the bottom surface of the groove, and the p-electrode 524 is formed on the p-layer 522. As described above, the light emitting element in the fifth embodiment is manufactured.

Next, the formation method of the quantum well structure layer 518C will be described in detail. The well layer of the quantum well structure layer 518C is InGaN having In composition of 35% or more, and it has been difficult to obtain a high-quality crystal. The inventors have conducted intensive research and development to obtain high-quality InGaN having a In composition of 35% or more, and found a method for obtaining high-quality InGaN. The method will be described below.

The growth temperature of the quantum well structure layer 518C is set to be 700° C. or lower. The lower limit of the growth temperature is, for example, 550° C. By setting the growth temperature to be in the vicinity of the decomposition temperature (630° C.) of InN, it is possible to curtail decomposition and re-evaporation of InN, and it is possible to form InGaN having a high In composition (particularly, In composition of 35% or more). The temperature is preferably 650° C. or lower, more preferably 610° C. to 650° C., still more preferably 620° C. to 640° C., and most preferably 625° C. to 635° C.

The growth rate of the quantum well structure layer 518C is set to be 0.8 nm/min or less. This is for the purpose of curtailing surface roughness, abnormal growth, and droplets due to insufficient migration of the raw material atoms at a low growth temperature. The droplet is made by forming a lump of In on the crystal surface. It is preferably 0.75 nm/min or less, more preferably 0.7 nm/min or less, and still more preferably 0.5 nm/min or less. The lower limit of the growth rate is not particularly limited, but if the growth rate is too slow, it takes time to form the quantum well structure layer 518C, and therefore the growth rate is preferably 0.05 nm/min or more.

The In solid phase ratio/In gas phase ratio is set to 0.75 to 1. Here, the In gas phase ratio is a molar ratio of In to the entire group-III metal in the source gas when forming InGaN. The In solid phase ratio is a molar ratio of In to the entire group-III metal in the InGaN crystal to be formed. The In solid phase ratio/In gas phase ratio can be controlled by a growth temperature, an In gas phase ratio, a VIII ratio, and the like. By setting the In solid phase ratio/In gas phase ratio within such a range, abnormal growth and droplets of InGaN can be curtailed. The In solid phase ratio/In gas phase ratio is more preferably 0.85 to 1, and still more preferably 0.9 to 1.

By setting the growth temperature, the growth rate, and the In solid phase ratio/In gas phase ratio within the above ranges, a high-quality crystal can be obtained even with InGaN having an In composition of 35% or more. Since the growth temperature is made as low as 700° C. or lower as described above, the decomposition efficiency of ammonia becomes low, migration of raw material atoms is less likely to occur, and high-quality InGaN is less likely to be obtained. However, by setting the growth rate within the above range, such a problem can be solved, and high-quality InGaN can be obtained.

The In gas phase ratio is preferably made 40% or more. The In solid phase ratio/In gas phase ratio can be easily controlled within the above range, and abnormal growth and droplets of InGaN can be curtailed. The In gas phase ratio is preferably made 55% or less.

The partial pressure of the Ga source gas is preferably made 1×10⁻⁶ atm to 3×10⁻⁶ atm, and the partial pressure of the In source gas is preferably made 1×10⁻⁶ atm to 3×10⁻⁶ atm. This is for the purpose of curtailing abnormal growth of InGaN and stabilizing the growth rate. The Ga source gas is, for example, trimethylgallium (TMG) or triethylgallium (TEG), and the In source gas is, for example, trimethylindium (TMI).

The growth rate of the barrier layer of the quantum well structure layer 518C is preferably equal to or higher than the growth rate of the well layer of the quantum well structure layer 518C. The growth temperature of the barrier layer of the quantum well structure layer 518C is preferably equal to or higher than the growth temperature of the well layer of the quantum well structure layer 518C. In the case of increasing the temperature, a first barrier layer of 2 nm to 20 nm may be formed at the same temperature as the growth temperature of the well layer, and then the temperature may be increased and a second barrier layer may be laminated. This makes it possible to prevent the well layer having a high In composition from being thermally decomposed during temperature rise. The first barrier layer and the second barrier layer may be InGaN having In composition lower than that of the well layer. Of course, GaN, AlGaN, or AlGaInN may be used, or a combination thereof may be used.

The partial pressure of the N source gas is preferably made 0.15 atm to 0.2 atm. Decomposition and re-evaporation of InN by H₂ generated by decomposition of ammonia can be curtailed, and the quality of InGaN can be improved. Nitrogen in the carrier gas is not the N source gas.

VIII ratio (molar ratio of ammonia to III metal source gas) is preferably set to be 30000 to 80000. When the ratio falls within this range, the quality of InGaN can be improved.

The growth temperature of the quantum well structure layer 518C is preferably made lower than the growth temperature of the first strain relaxation layer 518A and the second strain relaxation layer 518B. This is for the purpose of preventing thermal damage to the first strain relaxation layer 518A and the second strain relaxation layer 518B. The growth temperature of the second strain relaxation layer 518B is preferably made lower than the growth temperature of the first strain relaxation layer 518A.

The growth rate of the quantum well structure layer 518C is preferably made lower than the growth rates of the first strain relaxation layer 518A and the second strain relaxation layer 518B. The quantum well structure layer 518C can be formed with higher quality. The growth rate of the second strain relaxation layer 518B is preferably made lower than the growth rate of the first strain relaxation layer 518A.

The In gas phase ratio during formation of the quantum well structure layer 518C is preferably smaller than the In gas phase ratio during formation of the first strain relaxation layer 518A and the second strain relaxation layer 518B. The quantum well structure layer 518C can be formed with higher quality.

As described above, according to the fifth embodiment, it is possible to obtain high-quality crystals of InGaN with In composition of 35% or more, and particularly, it is possible to form InGaN serving as a red light emitting material with In composition of 40% or more. Therefore, the well layer in the quantum well structure layer 518C can be formed with high quality, and a light emitting element including a red emitting group-III nitride semiconductor with high light emission efficiency can be achieved.

### 12. Modifications of Fifth Embodiment

The active layer 518 of the light emitting element in the fifth embodiment can also be used as the third active layers 18 and 318 of the light emitting element in the first to fourth embodiments.

The formation method of InGaN in the fifth embodiment can be used not only for light emitting elements but also for InGaN such as solar cells and photocatalysts.

According to the fifth embodiment, not only InGaN with In composition of 35% or more but also a group-III nitride semiconductor with In composition of 35% or more can be improved in quality. For example, AlGaInN having In composition of 35% or more can also be improved in quality.

### 13. Experiment Results

Next, experiment results related to the fifth embodiment will be described.

13-1. Experiment 4

The quantum well structure layer 518C was formed by changing the growth rate. The growth temperature was 637° C., the In gas phase ratio was 47.5%, and the ammonia flow rate was 27 slm. The VIII ratio was set to 48000, 27000, and 20000, and the growth rates were set to 0.48 nm/min, 0.72 nm/min, and 0.96 nm/min, respectively. The In solid phase ratios were 42.0%, 40.0%, and 41.0%, respectively, and the In solid phase ratios/In gas phase ratios were 88.4%, 84.2%, and 86.3%, respectively.

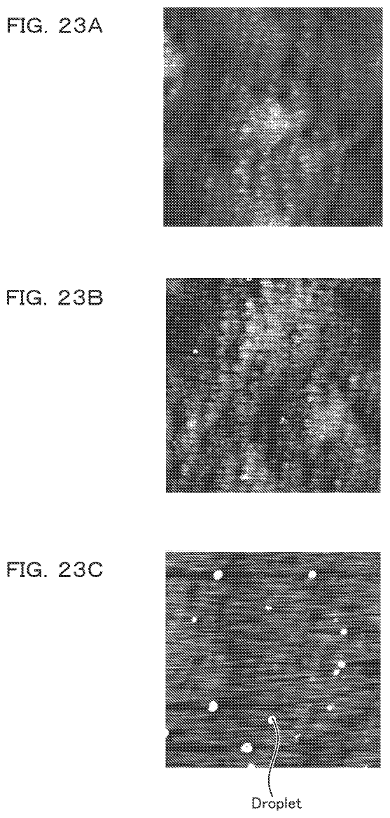

FIGS. 23A to 23C are AFM images of the well layer surface of the quantum well structure layer 518C when the growth rate is varied. It is a surface of an InGaN layer having a film thickness of 2 nm to 3 nm same as that of an actual well layer. FIG. 23A shows a case of a growth rate of 0.48 nm/min, FIG. 23B shows a case of a growth rate of 0.72 nm/min, and FIG. 23C shows a case of a growth rate of 0.96 nm/min.

As in FIG. 23A, in the case of the growth rate of 0.48 nm/min, few droplets were observed on the surface of the well layer, the density of the droplets was 1×10⁷ cm⁻², and the diameter of the droplets was about 30 nm.

As in FIG. 23B, in the case of the growth rate of 0.72 nm/min, more droplets were observed on the surface of the well layer than that in the case of the growth rate of nm/min, the density of the droplets was 1×10 8 cm⁻², and the diameter of the droplets was about 30 nm.

As in FIG. 23C, in the case of the growth rate of 0.96 nm/min, more droplets were observed on the surface of the well layer than that in the case of the growth rate of nm/min, the size thereof was also large, the density of the droplets was 4×10 8 cm⁻², and the diameter of the droplets was about 50 nm.

This result indicates that the growth rate of InGaN is preferably 0.75 nm/min or less and more preferably 0.5 nm/min for reducing droplets.

13-2. Experiment 5

The In solid phase ratio/In gas phase ratio was varied to form the quantum well structure layer 518C. The growth temperature was 637° C., the growth rate was 0.48 nm/min, and the ammonia flow rate was 27 slm. The VIII ratios were set to 40000, 40000, 48000, and 51000, and the In gas phase ratios were set to 57%, 52.5%, 47, 5%, and 45%, respectively. he In solid phase ratios were all 42.0%, and the In solid phase ratios/In gas phase ratios were 73.7%, 80.0%, 88.4%, and 93.3%, respectively.

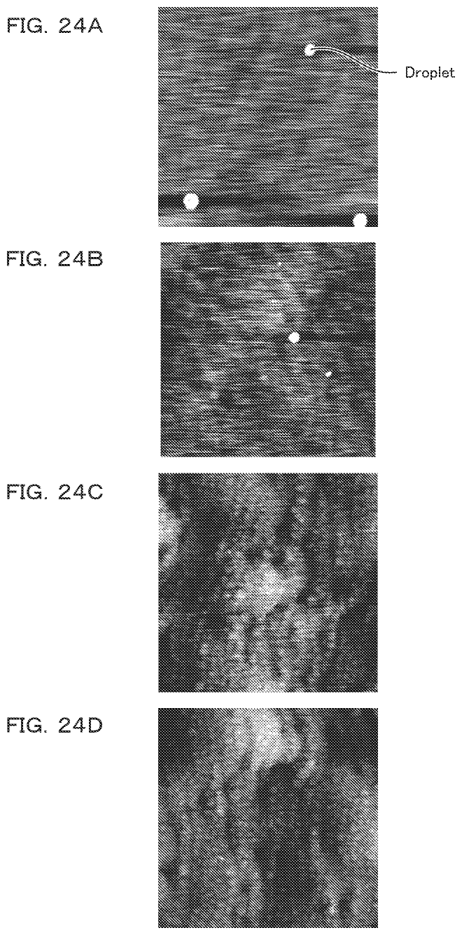

FIGS. 24A to 24D are AFM images of the surface of the well layer of the quantum well structure layer 518C when the In solid phase ratio/In gas phase ratio is varied. FIG. 24A shows a case of the In solid phase ratio/In gas phase ratio of 73.7%, FIG. 24B shows a case of the In solid phase ratio/In gas phase ratio of 80.0%, FIG. 24C shows a case of the In solid phase ratio/In gas phase ratio of 88.4%, and FIG. 24D shows a case of the In solid phase ratio/In gas phase ratio of 93.3%.

As in FIG. 24A, when the In solid phase ratio/In gas phase ratio was 73.7%, many droplets were observed on the surface of the well layer, the size of the droplets was large, the density of the droplets was 7.5×10⁷ cm⁻², and the diameter of the droplets was about 130 nm.

As in FIG. 24B, when the In solid phase ratio/In gas phase ratio was 80.0%, the number of droplets on the surface of the well layer was smaller and the size thereof was smaller than those when the In solid phase ratio/In gas phase ratio was 73.7%. The density of the droplets was 5.0×10⁷ cm⁻², and the diameter of the droplets was about 80 nm.

As in FIG. 24C, when the In solid phase ratio/In gas phase ratio was 88.4%, the number of droplets on the surface of the well layer was further smaller and the size thereof was also smaller than those when the In solid phase ratio/In gas phase ratio was 80.0%. The density of the droplets was 1.0×10⁷ cm⁻², and the diameter of the droplets was about 30 nm.

As in FIG. 24D, when the In solid phase ratio/In gas phase ratio was 93.3%, no droplets were observed on the surface of the well layer.

This result indicates that the In solid phase ratio/In gas phase ratio is preferably or more, more preferably 0.85 or more, and still more preferably 0.9 or more.

13-3. Experiment 6

The partial pressure of ammonia was varied to form the quantum well structure layer 518C. The growth temperature was 637° C. The flow rates of the carrier gas (nitrogen) were set to three stages of 142 slm, 130 slm, and 110 slm, the flow rates of ammonia were set to 15 slm, 27 slm, and 47 slm, respectively, and the partial pressures of ammonia were set to 0.096 atm, 0.172 atm, and 0.299 atm, respectively. The VIII ratios were set to 27000, 48000, and 85000, respectively, and the In gas phase ratios were set to 47.5% for all of them. The growth rate was 0.48 nm/min in all the cases, the In solid phase ratio became 40%, 42%, and 40%, respectively, and the In solid phase ratio/In gas phase ratio became 84.2%, 88.4%, and 84.2%, respectively.

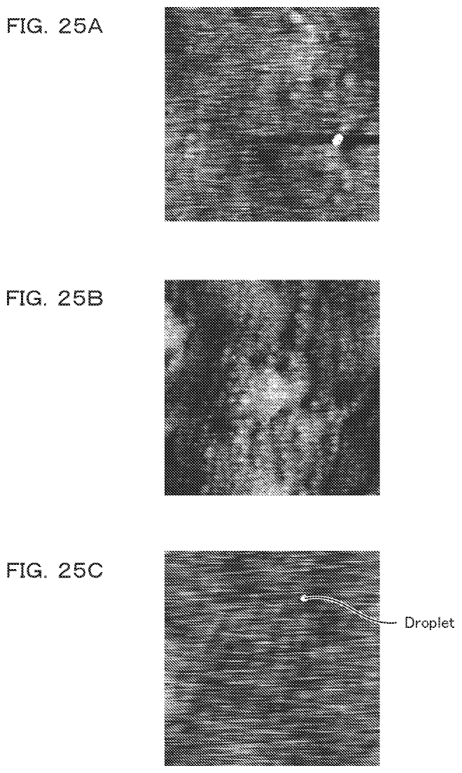

FIGS. 25A to 25C are AFM images of the well layer surface of the quantum well structure layer 518C when the partial pressure of ammonia is varied. FIG. 25A shows a partial pressure of ammonia of 0.096 atm, FIG. 25B shows a partial pressure of ammonia of 0.172 atm, and FIG. 25C shows a partial pressure of ammonia of 0.299 atm.

As in FIG. 25A, when the partial pressure of ammonia was 0.096 atm, droplets were observed on the surface of the well layer. The density of the droplets was 5.0×10⁷ cm⁻², and the diameter of the droplets was about 50 nm.

As in FIG. 25B, when the partial pressure of ammonia was 0.172 atm, droplets were observed on the surface of the well layer, but the number of droplets was smaller and the size thereof was smaller than those in the case where the partial pressure of ammonia was 0.096 atm. The density of the droplets was 1.0×10⁷ cm⁻², and the diameter of the droplets was about 30 nm.

As in FIG. 25C, when the partial pressure of ammonia was 0.299 atm, more droplets were observed on the surface of the well layer than those when the partial pressure of ammonia was 0.172 atm, and the size was also large. The density of the droplets was 5.0×10⁷ cm⁻², and the diameter of the droplets was about 50 nm.

This result indicates that the partial pressure of ammonia is preferably 0.15 atm to 0.2 atm. It was found that the VIII ratio was preferably 30000 to 80000.

The light emitting element of the present disclosure can be applied to a full-color display and so on.

We claim:

1. A light emitting element including a group-III nitride semiconductor, comprising:
an n-layer including an n-type group-III nitride semiconductor;
a first active layer provided on the n-layer and having a predetermined emission wavelength;
an intermediate layer provided on the first active layer and having a non-doped layer including a non-doped group-III nitride semiconductor and an n-type layer including an n-type group-III nitride semiconductor which are laminated in the order from the first active layer side;
a second active layer provided on the intermediate layer and having an emission wavelength different from that of the first active layer;
a groove reaching the non-doped layer from the second active layer side;
a first p-layer provided on the second active layer and including a p-type group-III nitride semiconductor;
a second p-layer provided on the non-doped layer exposed to a bottom surface of the groove and including a p-type group-III nitride semiconductor;
a first p-electrode provided on the first p-layer; and
a second p-electrode provided on the second p-layer.

2. The light emitting element according to claim 1, wherein a thickness of the intermediate layer is 150 nm or less, and each thickness of the non-doped layer and the n-type layer is 10 nm or more.

3. The light emitting element according to claim 1, wherein the intermediate layer includes a group-III nitride semiconductor containing In, and has an In composition set so as to have a band gap that does not absorb light emitted from the first active layer and the second active layer.

4. The light emitting element according to claim 1, wherein
the second active layer is structured so that a strain relaxation layer having a quantum well structure in which a thickness of a well layer is adjusted not to emit light and a light emitting layer having a quantum well structure and emitting light are laminated in the order from the intermediate layer side, and
a wavelength corresponding to band edge energy of the well layer of the strain relaxation layer is set to be shorter than an emission wavelength of the light emitting layer.

5. A light emitting element including a group-III nitride semiconductor, comprising:
an n-layer including an n-type group-III nitride semiconductor;
a first active layer provided on the n-layer and having a predetermined emission wavelength;
an intermediate layer provided on the first active layer and including a group-III nitride semiconductor containing In; and
a second active layer provided on the intermediate layer and having an emission wavelength different from that of the first active layer, wherein
the intermediate layer has an In composition set so as to have a band gap that does not absorb light emitted from the first active layer and the second active layer.

6. The light emitting element according to claim 5, comprising:
a groove reaching the intermediate layer from the second active layer side;
a first p-layer provided on the second active layer and including a p-type group-III nitride semiconductor;
a second p-layer provided on the intermediate layer exposed to a bottom surface of the groove and including a p-type group-III nitride semiconductor;
a first p-electrode provided on the first p-layer; and
a second p-electrode provided on the second p-layer.

7. The light emitting element according to claim 5, wherein
the intermediate layer has a structure in which a p-type first layer, a p-type second layer, an n-type third layer, and an n-type fourth layer are laminated in the order from the first active layer side,
a p-type impurity concentration of the second layer is higher than a p-type impurity concentration of the first layer, an n-type impurity concentration of the third layer is higher than an n-type impurity concentration of the fourth layer, and the second layer and the third layer form a tunnel junction structure, and
the light emitting element further comprises
a p-layer provided on the second active layer,
a groove reaching the fourth layer from the p-layer side,
a p-electrode provided on the p-layer, and
an electrode provided on the fourth layer exposed to a bottom surface of the groove.

8. The light emitting element according to claim 7, wherein In compositions of the second layer and the third layer are higher than In compositions of the first layer and the fourth layer.

9. The light emitting element according to claim 7, wherein an In composition of the second layer is higher than an In composition of the third layer.

10. The light emitting element according to claim 7, wherein a thickness of the second layer is thinner than a thickness of the first layer, and a thickness of the third layer is thinner than a thickness of the fourth layer.

11. The light emitting element according to claim 5, wherein the intermediate layer is made of InGaN.

12. The light emitting element according to claim 5, wherein an In composition of the intermediate layer is 10% or less.

13. The light emitting element according to claim 5, wherein the intermediate layer is made of GaN doped with In.

14. A light emitting element including a group-III nitride semiconductor, comprising:
an n-layer including an n-type group-III nitride semiconductor;
a first active layer provided on the n-layer and having a predetermined emission wavelength;
an intermediate layer provided on the first active layer;
a second active layer provided on the intermediate layer and having an emission wavelength longer than the first active layer;
a groove reaching the intermediate layer from the second active layer side;
a first p-layer provided on the second active layer and including a p-type group-III nitride semiconductor;
a second p-layer provided on the intermediate layer exposed to a bottom surface of the groove and including a p-type group-III nitride semiconductor;
a first p-electrode provided on the first p-layer; and
a second p-electrode provided on the second p-layer, wherein
the second active layer is structured so that a strain relaxation layer having a quantum well structure in which a thickness of a well layer is adjusted not to emit light and a light emitting layer having a quantum well structure and emitting light are laminated in the order from the intermediate layer side, and
a wavelength corresponding to band edge energy of the well layer of the strain relaxation layer is set to be shorter than an emission wavelength of the light emitting layer.

15. The light emitting element according to claim 14, wherein a wavelength corresponding to band edge energy of the well layer of the strain relaxation layer is set to be equal to an emission wavelength of the first active layer.

16. The light emitting element according to claim 14, wherein a wavelength corresponding to band edge energy of the well layer of the strain relaxation layer is set to be shorter by 40 nm to 100 nm than an emission wavelength of the light emitting layer.

17. The light emitting element according to claim 14, wherein the strain relaxation layer has a SQW structure.

18. The light emitting element according to claim 14, wherein a ratio of a thickness of the first active layer to a thickness of the second active layer is 30% or less.
